(19) United States
(12) Patent Application Publication
(10) Pub. No.: US 2010/0019215 A1
(43) Pub. Date: Jan. 28, 2010

(54) MUSHROOM TYPE MEMORY CELL HAVING SELF-ALIGNED BOTTOM ELECTRODE AND DIODE ACCESS DEVICE

(75) Inventors: Hsiang-Lan Lung, Elmsford, NY (US); Chung Hon Lam, Peekskill, NY (US); Thomas D. Happ, Dresden (DE); Matthew J. Breitwisch, Yorktown Heights, NY (US); Alejandro Gabriel Schrott, New York, NY (US); Min Yang, Yorktown Heights, NY (US)

Correspondence Address: MACRONIX;C/O HAYNES BEFFEL & WOLFELD LLP, P. O. BOX 366, HALF MOON BAY, CA, 94019, US

(73) Assignees: Macronix International Co., Ltd., Hsinchu (TW); Qimonda North America Corp., Cary, NC (US); International Business Machines Corporation, Armonk, NY (US)

(21) Appl. No.: 12/177,435

(22) Filed: Jul. 22, 2008

(51) Int. Cl. H01L 47/00; H01L 21/00

(52) U.S. Cl. 257/2; 257/202; 438/102; 438/128; 257/E47.001; 257/E21.001

(57) ABSTRACT

Memory devices are described along with methods for manufacturing. A memory device as described herein includes a plurality of word lines extending in a first direction, and a plurality of bit lines overlying the plurality of word lines and extending in a second direction. A plurality of memory cells are at cross-point locations. Each memory cell comprises a diode having first and second sides aligned with sides of a corresponding word line. Each memory cell also includes a bottom electrode self-centered on the diode, the bottom electrode having a top surface with a surface area less than that of the top surface of the diode. Each of the memory cells includes a strip of memory material on the top surface of the bottom electrode, the strip of memory material underlying and in electrical communication with a corresponding bit line.

### BACKGROUND OF THE INVENTION

1. Field of the Invention

The present invention relates to high density memory devices based on phase change based memory materials, including chalcogenide based materials and other programmable resistive materials, and to methods for manufacturing such devices.

2. Description of Related Art

Phase change based memory materials, like chalcogenide based materials and similar materials, can be caused to change phase between an amorphous state and a crystalline state by application of electrical current at levels suitable for implementation in integrated circuits. The generally amorphous state is characterized by higher electrical resistivity than the generally crystalline state, which can be readily sensed to indicate data. These properties have generated interest in using programmable resistive material to form nonvolatile memory circuits, which can be read and written with random access.

The change from the amorphous to the crystalline state is generally a lower current operation. The change from crystalline to amorphous, referred to as reset herein, is generally a higher current operation, which includes a short high current density pulse to melt or breakdown the crystalline structure, after which the phase change material cools quickly, quenching the phase change process and allowing at least a portion of the phase change material to stabilize in the amorphous state. It is desirable to minimize the magnitude of the reset current used to cause transition of phase change material from the crystalline state to the amorphous state.

The magnitude of the current needed for reset can be reduced by reducing the size of the phase change material element in the cell and/or the contact area between electrodes and the phase change material, such that higher current densities are achieved with small absolute current values through the phase change material element.

One approach to controlling the size of the active area in a phase change cell is to devise very small electrodes for delivering current to a body of phase change material. This small electrode structure induces phase change in the phase change material in a small area like the head of a mushroom, at the location of the contact. See, U.S. Pat. No. 6,429,064 issued Aug. 6, 2002 to Wicker, “Reduced Contact Areas of Sidewall Conductor”; U.S. Pat. No. 6,462,353 issued Oct. 8, 2002 to Gilgen, “Method for Fabricating a Small Area of Contact Between Electrodes”; U.S. Pat. No. 6,501,111 issued Dec. 31, 2002 to Lowrey, “Three-Dimensional (3D) Programmable Device”; U.S. Pat. No. 6,563,156 issued Jul. 1, 2003 to Harshfield, “Memory Elements and Methods for Making Same.”

Problems have arisen in manufacturing devices with very small dimensions, and with variations in manufacturing processes needed to meet the tight tolerance requirements necessary for large-scale high-density memory devices.

It is therefore desirable to provide memory cell structures having small dimensions and low reset currents, and methods for manufacturing such structures addressing the tight tolerance requirements needed for large-scale high-density memory devices.

### SUMMARY OF THE INVENTION

A memory device as described herein includes a plurality of word lines extending in a first direction, and a plurality of bit lines overlying the plurality of word lines and extending in a second direction. The bit lines cross-over the word lines at cross-point locations. The device includes a plurality of memory cells at the cross-point locations. Each memory cell includes a diode having first and second sides aligned with sides of a corresponding word line in the plurality of word lines, the diode having a top surface. Each memory cell also includes a bottom electrode self-centered on the diode, the bottom electrode having a top surface with a surface area less than that of the top surface of the diode. Each memory cell further includes a strip of memory material on the top surface of the bottom electrode, the strip of memory material underlying and in electrical communication with a corresponding bit line in the plurality of bit lines.

A method for manufacturing a memory device as described herein includes forming a structure comprising word line material, diode material on the word line material, first material on the diode material, and a second material on the first material. A plurality of dielectric-filled first trenches are formed in the structure extending in a first direction to define a plurality of strips, each strip including a word line comprising word line material. A plurality of dielectric-filled second trenches are formed down to the word lines and extending in a second direction to define a plurality of stacks. Each stack includes a diode comprising the diode material on a corresponding word line and having a top surface, a first element comprising first material on the diode, and a second element comprising second material on the first element. A plurality of bottom electrodes are formed using the first elements and the second elements of the stacks. Strips of memory material are formed on top surfaces of the bottom electrodes and bit lines are formed on the strips of memory material.

A memory cell described herein resulting in the active region within the memory element that can be made extremely small, thus reducing the magnitude of the current needed to induce a phase change. The thickness of the strips of memory material can be established using thin film deposition techniques. Furthermore, the bottom electrode has a top surface with a surface area less than that of the top surface of the diode. Additionally, the width of the bottom electrode is less than that of the diode, and is preferably less than a minimum feature size for a process, typically a lithographic process, used to form the word lines and bit lines of the memory device. The small bottom electrode concentrates current density in the portion of the memory element adjacent the top surface of the bottom electrode, thereby reducing the magnitude of the current needed to induce a phase change in the active region. Additionally, in embodiments dielectric material surrounding the bottom electrode can provide some thermal isolation to the active region, which also helps to reduce the amount of current necessary to induce a phase change.

Memory arrays having memory cells as described herein result in high density memory. In embodiments the cross-sectional area the memory cells of the array is determined entirely by dimensions of the word lines and bit lines, allowing for a high memory density for array. The word lines have word line widths and adjacent word lines are separated by a word line separation distance, and the bit lines have bit line widths and adjacent bit lines are separated by a bit line separation distance. In preferred embodiments the summation of the word line width and the word line separation distance is equal to twice a feature size F used to form the array, and the summation of the bit line width and the bit line separation distance is equal to twice the feature size F. Additionally, F is preferably a minimum feature size for a process (typically a lithographic process) used to form the bit lines and word lines, such that the memory cells of the array have a memory cell area of 4F².

Other aspects and advantages of the present invention can be seen on review of the drawings, the detailed description and the claims, which follow.

### BRIEF DESCRIPTION OF THE DRAWINGS

FIG. 1 illustrates a schematic diagram of a portion of a cross-point array implemented using mushroom type memory cells having self-aligned bottom electrodes and diode access devices as described herein.

FIGS. 2A and 2B illustrate cross-sectional views of a first embodiment of memory cells arranged in the cross-point array.

FIGS. 3A and 3B illustrate cross-sectional views of a second embodiment of memory cells arranged in the cross-point array.

FIGS. 4A and 4B illustrate cross-sectional views of a third embodiment of memory cells arranged in the cross-point array

FIGS. 5-14 illustrate steps in a fabrication sequence for manufacturing the cross point array of memory cells as illustrated in FIGS. 3A-3B.

FIGS. 15-16 illustrate an alternative manufacturing embodiment to that illustrated in FIGS. 12-13, resulting in memory cells as illustrated in FIGS. 3A-3B

FIGS. 17-26 illustrate an alternative manufacturing embodiment to that illustrated in FIGS. 10- 14.

FIG. 27 illustrates an alternative embodiment to that of FIG. 20 for forming the bottom electrodes, illustrating the formation of the bottom electrode having a ring-shape top surface.

FIGS. 28-29 illustrate an alternative manufacturing technique to that illustrated in FIGS. 21-24.

FIG. 30 is a simplified block diagram of an integrated circuit including a cross-point memory array of memory cells having self-aligned bottom electrodes and diode access devices as described herein.

### DETAILED DESCRIPTION

The following description of the invention will typically be with reference to specific structural embodiments and methods. It is to be understood that there is no intention to limit the invention to the specifically disclosed embodiments and methods but that the invention may be practiced using other features, elements, methods and embodiments. Preferred embodiments are described to illustrate the present invention, not to limit its scope, which is defined by the claims. Those of ordinary skill in the art will recognize a variety of equivalent variations on the description that follows. Like elements in various embodiments are commonly referred to with like reference numerals.

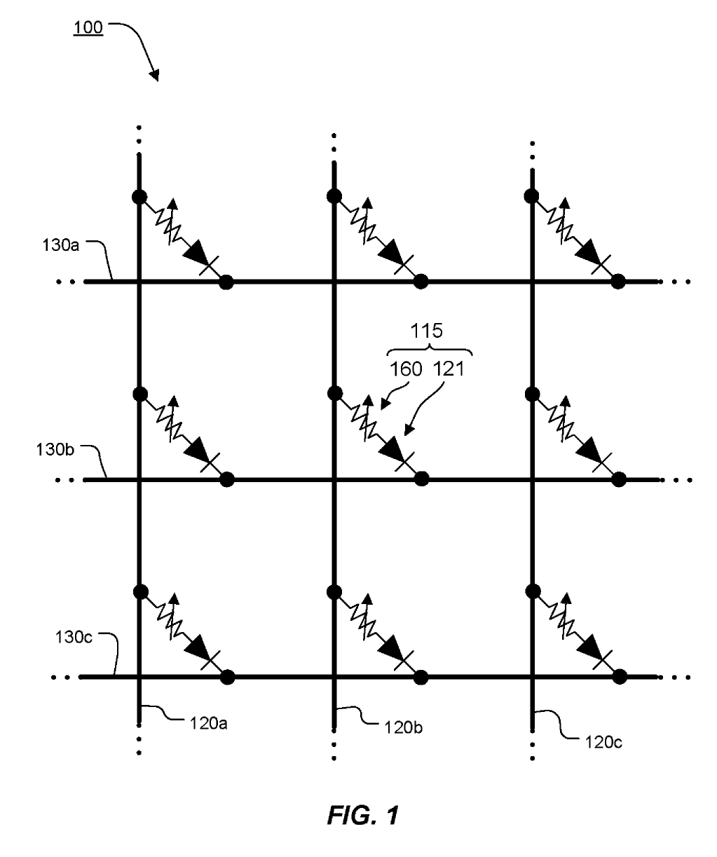

FIG. 1 illustrates a schematic diagram of a portion of a cross-point memory array 100 implemented using mushroom type memory cells having self-aligned bottom electrodes and diode access devices as described herein.

As shown in the schematic diagram of FIG. 1, each of the memory cells of array 100 includes a diode access device and a memory element (represented in FIG. 1 by a variable resistor) capable of being set to one of a plurality of resistive states and thus capable of storing one or more bits of data.

The array 100 comprises a plurality of word lines 130 including word lines 130a, 130b, and 130c extending in parallel in a first direction, and a plurality of bit lines 120 including bit lines 120a, 120b, and 120c extending in parallel in a second direction perpendicular to the first direction. The array 100 is referred to as a cross-point array because the word lines 130 and bit lines 120 are arranged in such a manner that a given word line 130 and a given bit line 120 cross over each other but do not physically intersect, and the memory cells are located at these cross-point locations of the word lines 130 and bit lines 120.

Memory cell 115 is representative of the memory cells of array 100 and is arranged at the cross-point location of the bit line 120b and word line 130b, the memory cell 115 comprising a diode 121 and memory element 160 arranged in series, the diode 121 electrically coupled to the word line 130b and the memory element 160 electrically coupled to the bit line 120b.

Reading or writing to memory cell 115 of array 100 can be achieved by applying appropriate voltages and/or currents to the corresponding word line 130b and bit line 120b to induce a current through a selected memory cell 115. The level and duration of the voltages/currents applied is dependent upon the operation performed, e.g. a reading operation or a writing operation.

In a reset (or erase) operation of memory cell 115 having memory element 160 comprising phase change material, a reset pulse is applied to the corresponding word line 130b and bit line 120b to cause a transition of an active region of the phase change material into an amorphous phase, thereby setting the phase change material to a resistance within a resistive value range associated with the reset state. The reset pulse is a relatively high energy pulse, sufficient to raise the temperature of at least the active region of the memory element 160 above the transition (crystallization) temperature of the phase change material and also above the melting temperature to place at least the active region in a liquid state. The reset pulse is then quickly terminated, resulting in a relatively quick quenching time as the active region quickly cools to below the transition temperature so that the active region stabilizes to an amorphous phase.

In a set (or program) operation of memory cell 115 having memory element 160 comprising phase change material, a program pulse is applied to the corresponding word line 130b and bit line 120b of suitable amplitude and duration to induce a current sufficient to raise the temperature of at least a portion of the active region above the transition temperature and cause a transition of a portion of the active region from the amorphous phase into a crystalline phase, this transition lowering the resistance of the memory element 160 and setting the memory cell 115 to the desired state.

In a read (or sense) operation of the data value stored in memory cell 115 having memory element 160 comprising phase change material, a read pulse is applied to the corresponding word line 130b and bit line 120b of suitable amplitude and duration to induce current to flow that does not result in the memory element 160 undergoing a change in resistive state. The current through the memory cell 115 is dependent upon the resistance of the memory element 160 and thus the data value stored in the memory cell 115.

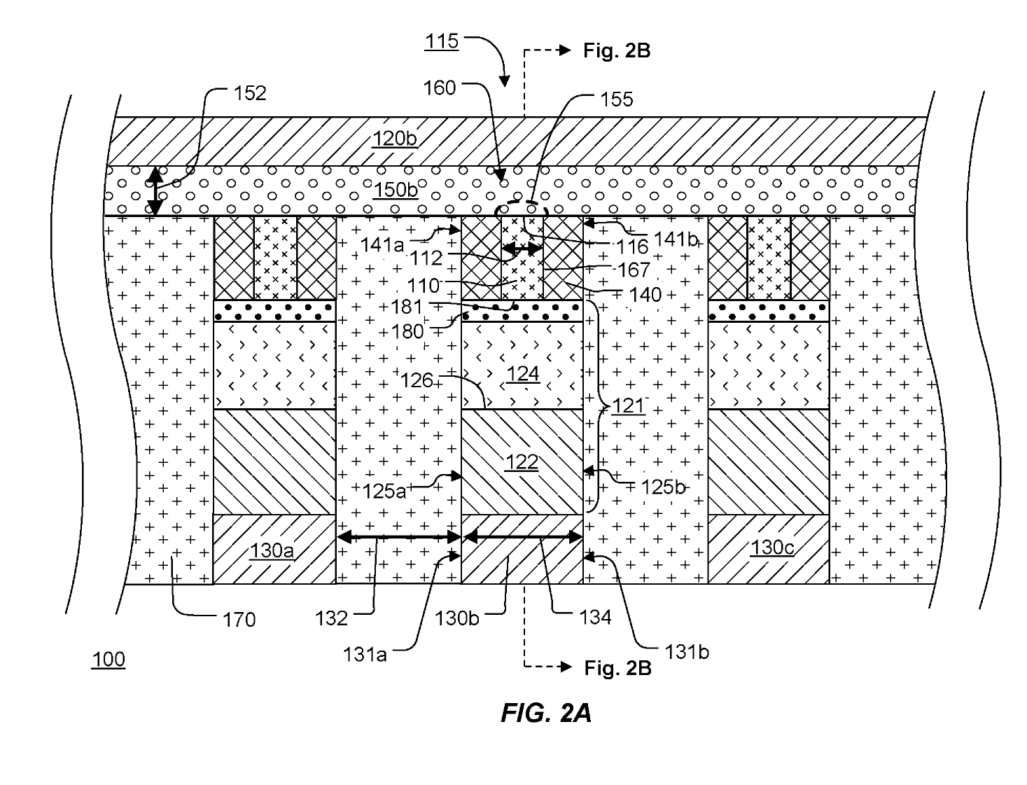

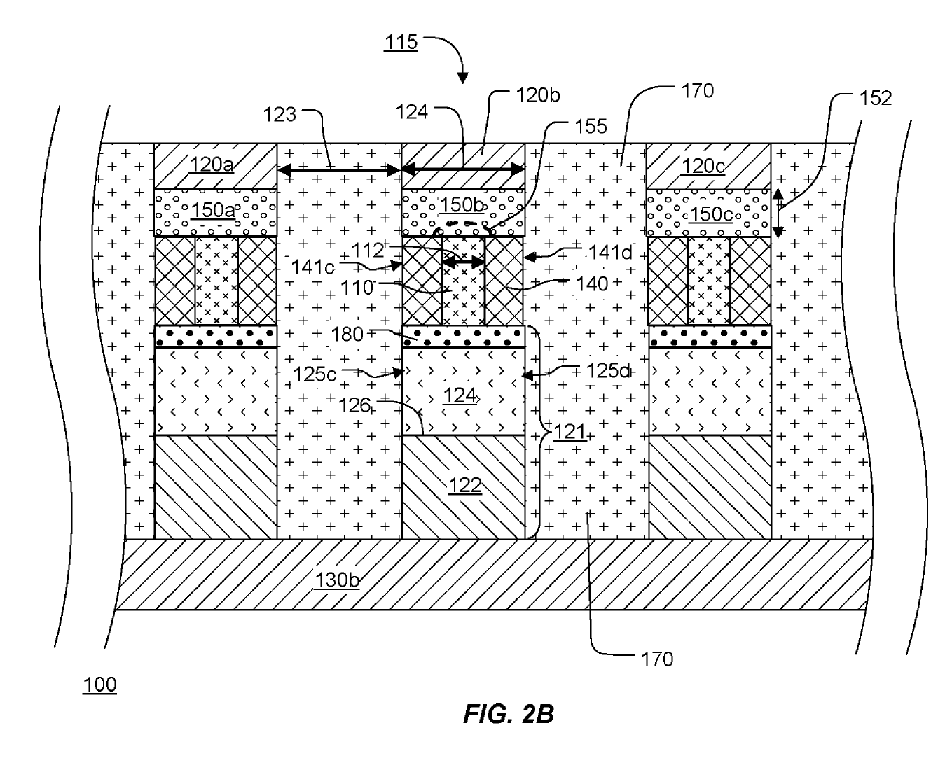

FIGS. 2A and 2B illustrate cross-sectional views of a portion of a first embodiment of memory cells (including representative memory cell 115) arranged in the cross-point array 100, FIG. 2A taken along the bit lines 120 and FIG. 2B taken along the word lines 130.

Referring to FIGS. 2A and 2B, the memory cell 115 includes a first doped semiconductor region 122 having a first conductivity type and a second doped semiconductor region 124 on the first doped semiconductor region 122, the second doped semiconductor region 124 having a second conductivity type opposite the first conductivity type. The first doped semiconductor region 122 and the second doped semiconductor region 124 define a pn junction 126 therebetween.

The memory cell 115 includes a conductive cap 180 on the second doped semiconductor region 124. The first and second doped semiconductor regions 122, 124 and the conductive cap 180 form a stack defining diode 121. In the illustrated embodiment the conductive cap 180 comprises a silicide containing, for example, Ti, W, Co, Ni, or Ta. The conductive cap 180 assists in maintaining the uniformity of an electric field impressed across the first and second doped semiconductor regions 122, 124 during operation by providing a contact surface that is more highly conductive than the semiconductor material of the first and second doped semiconductor regions 122, 124. The conductive cap 180 also provides a low resistance ohmic contact between the diode 121 and the bottom electrode 1 10. Additionally, the conductive cap 180 can be used as a protective etch stop layer for the second doped semiconductor region 124 during the manufacturing of the memory cell 100.

The first doped semiconductor region 122 is on word line 130b, the word line 130b extending into and out of the cross-section illustrated in FIG. 2A. In the illustrated embodiment the word lines 130 comprise doped N⁺ (highly doped N-type) semiconductor material, the first doped semiconductor region 122 comprises doped N⁻ (lightly doped N-type) semiconductor material, and the second doped semiconductor region 124 comprises doped P⁺ (highly doped P-type) semiconductor material. It has been observed that the breakdown voltage of diode 121 comprising can be increased by increasing the distance between the P+ doped region and the N+ doped region and/or decreasing the doping concentration in the N⁻ region.

In an alternative embodiment the word lines 130 may comprise other conductive materials such as W, TiN, Ta, Al. In yet another alternative embodiment the first doped semiconductor region 122 may be omitted and the diode 121 formed from the second doped semiconductor region 124, the conductive cap 180 and a portion of word line 130b.

A bottom electrode 110 is on the diode 121 and couples the diode 121 to a memory element 160 comprising a portion of memory material strip 150b underlying bit line 120b. The memory material may comprise, for example, one or more materials from the group of Ge, Sb, Te, Se, In, Ti, Ga, Bi, Sn, Cu, Pd, Pb, Ag, S, Si, O, P, As, N and Au.

The bottom electrode 110 may comprise, for example, TiN or TaN. TiN may be preferred in embodiments in which memory element 160 comprises GST (discussed below) because it makes good contact with GST, it is a common material used in semiconductor manufacturing, and it provides a good diffusion barrier at the higher temperatures at which GST transitions, typically in the 600-700° C. range. Alternatively, the bottom electrode may be TiAlN or TaAlN, or comprises, for further examples, one or more elements selected from the group consisting of Ti, W, Mo, Al, Ta, Cu, Pt, Ir, La, Ni, N, O, and Ru and combinations thereof.

A dielectric spacer 140 contacts an outer surface 167 of the bottom electrode 110 and surrounds the bottom electrode 110. The dielectric spacer 140 preferably comprises material resistance to diffusion of the phase change material of memory element 160. In some embodiments the material of dielectric spacer 140 is chosen for low thermal conductivity for reasons discussed in more detail below. The dielectric spacer 140 has sides 141 aligned with sides 125 of the diode 121.

The bit lines 120, including bit line 120b acting as a top electrode for the memory cell 115, extend into and out of the cross-section illustrated in FIG. 2B. The bit lines 120 comprise a conductive material such as one more of the materials described above with reference to the bottom electrode 110.

Dielectric 170, comprising one or more layers of dielectric material, surrounds the memory cells and separates adjacent word lines 130 and adjacent bit lines 120.

In operation voltages on the word line 130b and the bit line 120b can induce a current through the memory element 160, bottom electrode 110, and the diode 121.

The active region 155 is the region of the memory element 160 in which the memory material is induced to change between at least two solid phases. As can be appreciated, the active region 155 can be made extremely small in the illustrated structure, thus reducing the magnitude of the current needed to induce a phase change. The thickness 152 of the strips of memory material 150 can be established using thin film deposition techniques. In some embodiments the thickness 152 is less than 100 nm, for example being between 10 and 100 nm. Furthermore, the bottom electrode 110 has a top surface 116 with a surface area less than that of the top surface 181 of the diode 121. Additionally, the width 112 of the bottom electrode 110 is less than that of the diode 121, and is preferably less than a minimum feature size for a process, typically a lithographic process, used to form the word lines 130 and bit lines 120 of the memory array 100. The small bottom electrode 110 concentrates current density in the portion of the memory element 160 adjacent the top surface 116 of the bottom electrode 110, thereby reducing the magnitude of the current needed to induce a phase change in the active region 155. Additionally, the dielectric spacer 140 preferably comprises material providing some thermal isolation to the active region 155, which also helps to reduce the amount of current necessary to induce a phase change.

As can be seen in the cross-sections illustrated in FIGS. 2A and 2B, the memory cells of the array 100 are arranged at the cross-point locations of the word lines 130 and bit lines 120. Memory cell 115 is representative and is arranged at the cross-point location of word line 130b and bit line 120b. Additionally, the diode 121 and the dielectric spacer 140 of memory cell 115 have a first width substantially the same as the width 134 of the word lines 130 (See FIG. 2A). Furthermore, the diode 121 and the dielectric spacer 140 have a second width substantially the same as the width 124 of the bit lines 120 (See FIG. 2B). Therefore, the cross-sectional area the memory cells of array 100 is determined entirely by dimensions of the word lines 130 and bit lines 120, allowing for a high memory density for array 100.

The word lines 130 have word line widths 134 and adjacent word lines 130 are separated by a word line separation distance 132 (See FIG. 2A), and the bit lines 120 have bit line widths 124 and adjacent bit lines 120 are separated by a bit line separation distance 123 (See FIG. 2B). In preferred embodiments the summation of the word line width 134 and the word line separation distance 132 is equal to twice a feature size F used to form the array 100, and the summation of the bit line width 124 and the bit line separation distance 123 is equal to twice the feature size F. Additionally, F is preferably a minimum feature size for a process (typically a lithographic process) used to form the bit lines 120 and word lines 130, such that the memory cells of array 100 have a memory cell area of 4F².

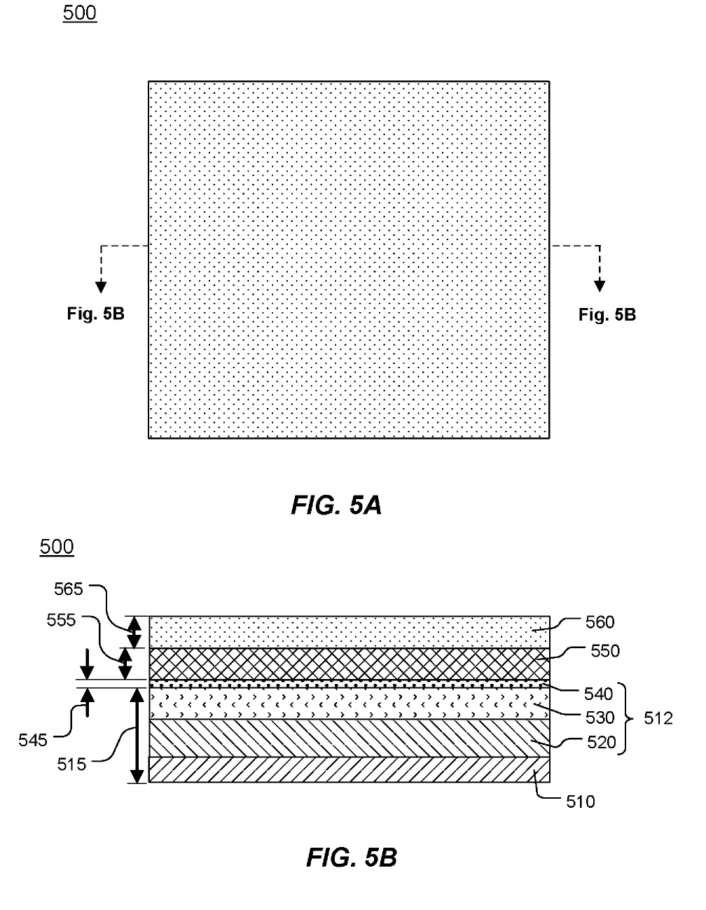

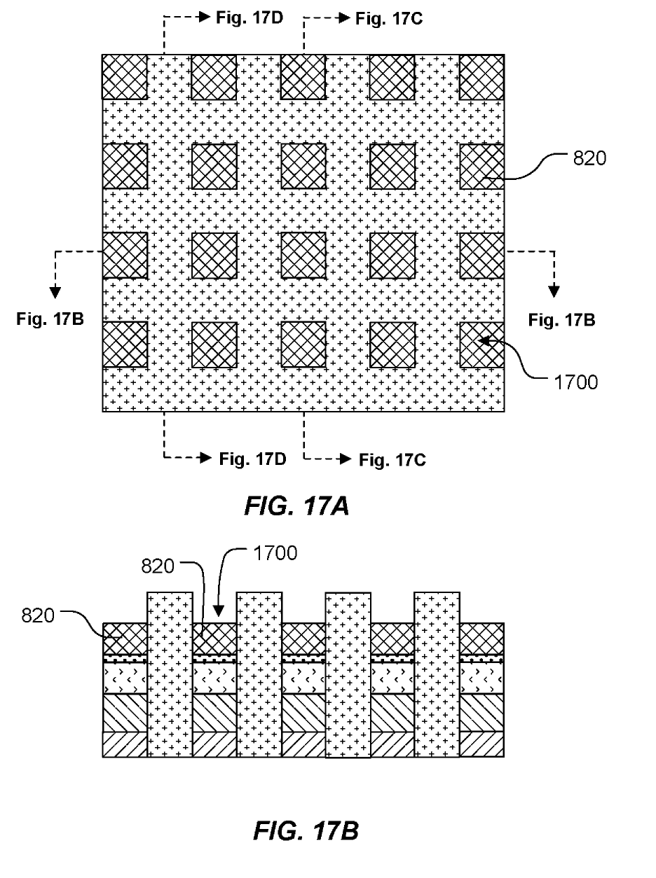

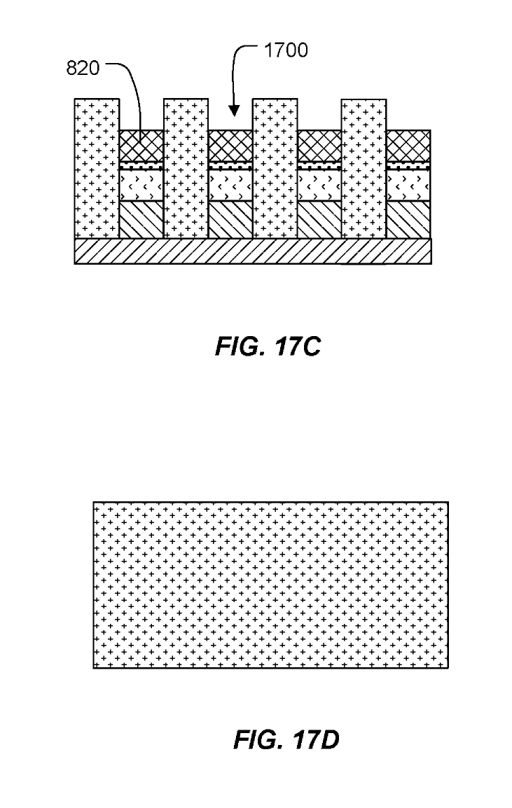

In the memory array illustrated in FIGS. 2A-2B, the bottom electrode 110 is self-centered on the diode 121, and the diode 121 has first and second sides 125a, 125b aligned with sides 131a, 131b of the underlying word line 130b. In a first manufacturing embodiment (described in more detail with respect to FIGS. 17-20 below) the sidewall spacer 140 defines an opening in which the bottom electrode 110 is formed, and in a second manufacturing embodiment (described in more detail with respect to FIGS. 5-14) the bottom electrode 110 and the dielectric 170 define an opening in which the sidewall spacer 140 is formed.

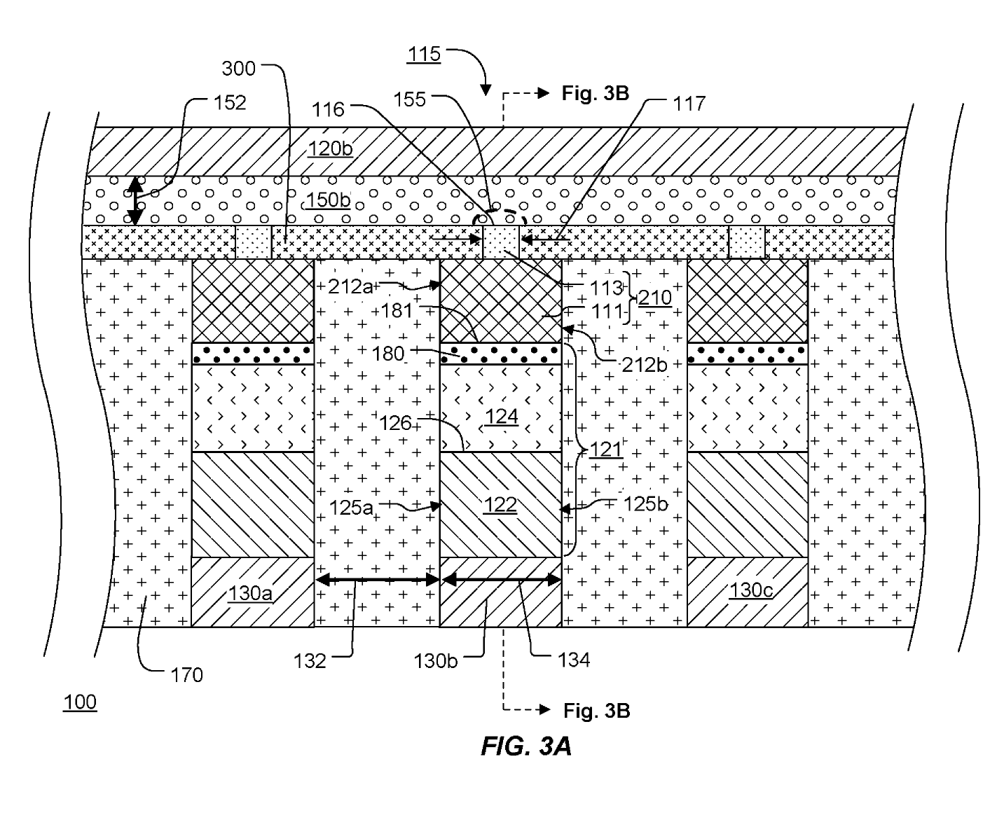

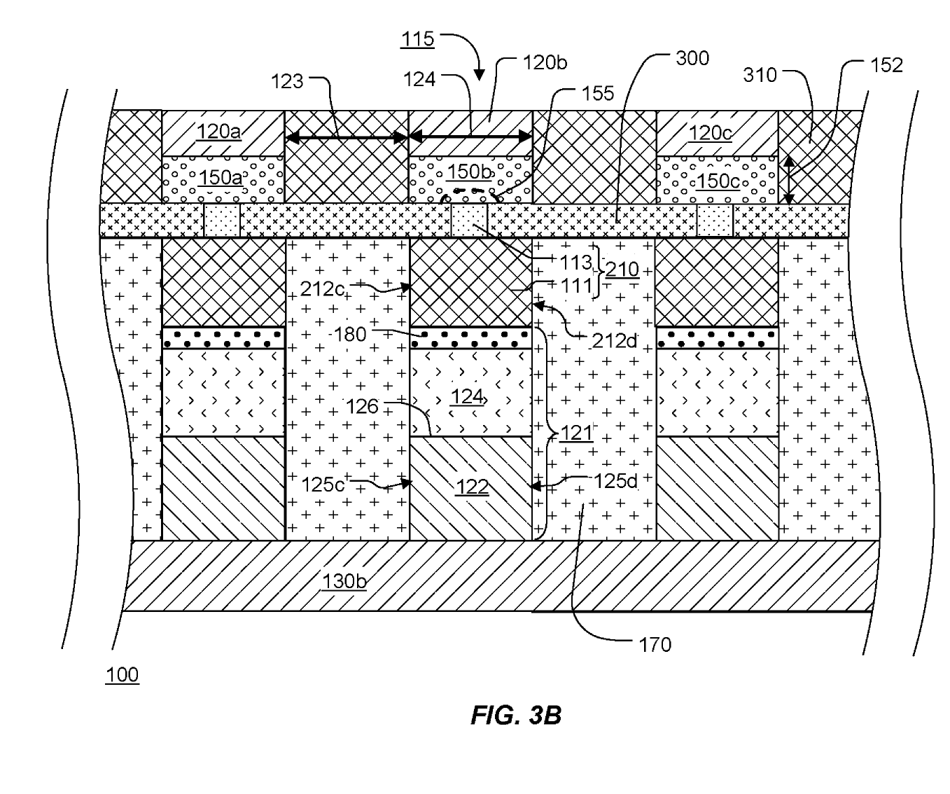

FIGS. 3A and 3B illustrate cross-sectional views of a portion of a second embodiment of memory cells (including representative memory cell 115) arranged in the cross-point array 100, FIG. 3A taken along the bit lines 120 and FIG. 3B taken along the word lines 130.

In the embodiment of FIGS. 3A and 3B, the bottom electrode 210 comprises a first conductive element 111 on the diode 121 and having sides 212 aligned with sides 125 of the diode, and a second conductive element 113 self-centered on the first conductive element 111, the second conductive element 113 having a width 117 less than that of the first conductive element 111. In the illustrated embodiment the first conductive element 111 comprises a conductive material such as TiN, and the second conductive element 113 comprises amorphous silicon.

A dielectric layer 300 is on a top surface of the first conductive elements 111 and the dielectric 170, the dielectric layer 300 surrounding the second conductive elements 113 of the bottom electrodes 210 As can be seen in FIG. 3B, a dielectric 310 also separates adjacent bit lines 120 and adjacent strips of memory material 150.

As can be appreciated, the active region 155 can be made extremely small in the illustrated structure, thus reducing the magnitude of the current needed to induce a phase change. The thickness 152 of the strips of memory material 150 can be established using thin film deposition techniques. Furthermore, the bottom electrode 210 has a top surface 116 with a surface area less than that of the top surface 181 of the diode 121 Additionally, the width 117 of the bottom electrode 210 is less than that of the diode 121, and is preferably less than a minimum feature size for a process, typically a lithographic process, used to form the word lines 130 and bit lines 120 of the memory array 100. The small second conductive element 113 concentrates current density in the portion of the memory element 160 adjacent the top surface 116 of the bottom electrode 210, thereby reducing the magnitude of the current needed to induce a phase change in the active region 155. Additionally, the dielectric layer 300 preferably comprises material providing some thermal isolation to the active region 155, which also helps to reduce the amount of current necessary to induce a phase change.

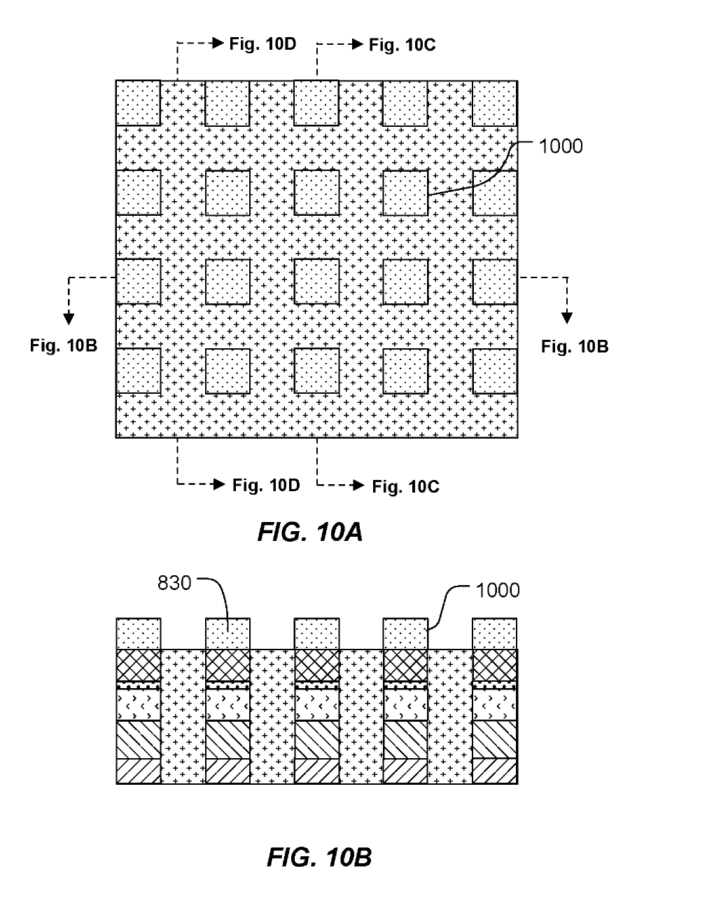

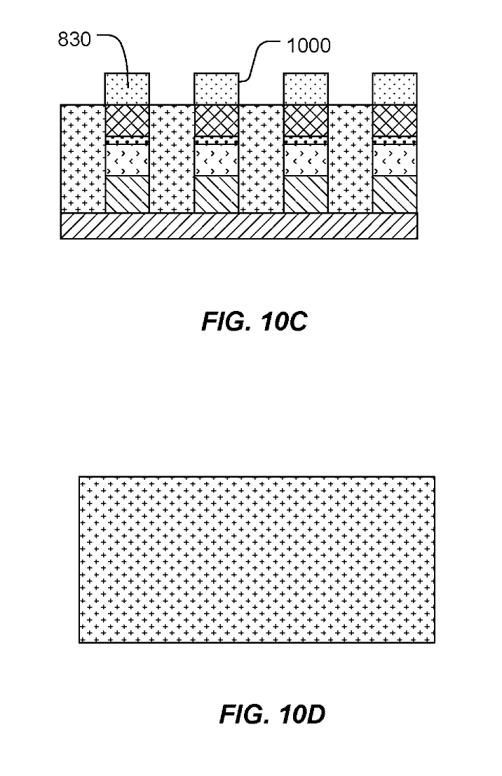

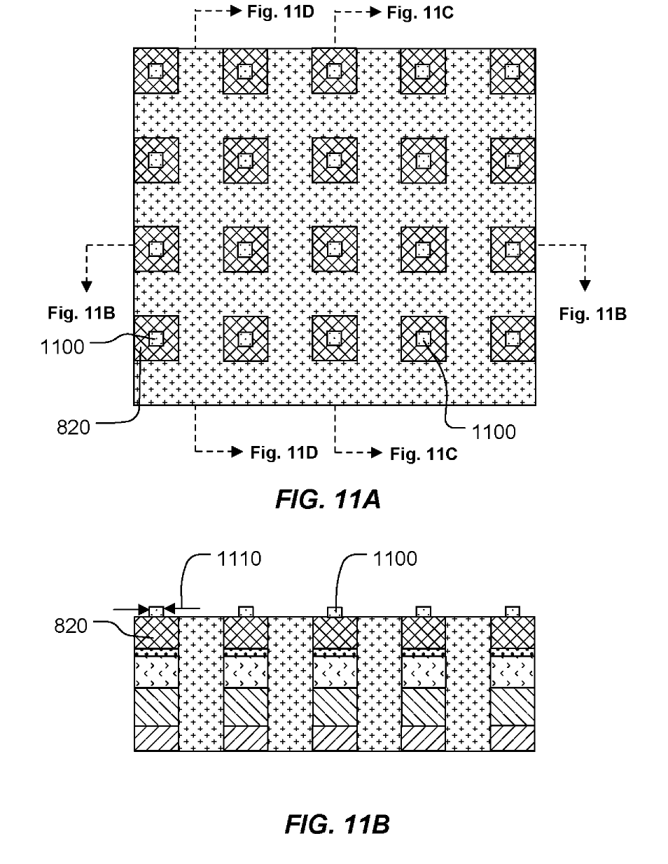

In the embodiment illustrated in FIGS. 3A-3B, the first conductive element 111 has sides 212 aligned with the sides 125 of the diode 121, and the second conductive element 113 is self-centered on the first conductive element 111. As described in more detail with respect to FIGS. 10-11 and FIGS. 15-16 below, the material for the first conductive element 111 and the second conductive element 113 are first patterned during the formation of the diode 121, and then material of the second conductive element 113 is anisotropically etched to form the second conductive element 113 having a width 117 less than that of the first conductive element 111.

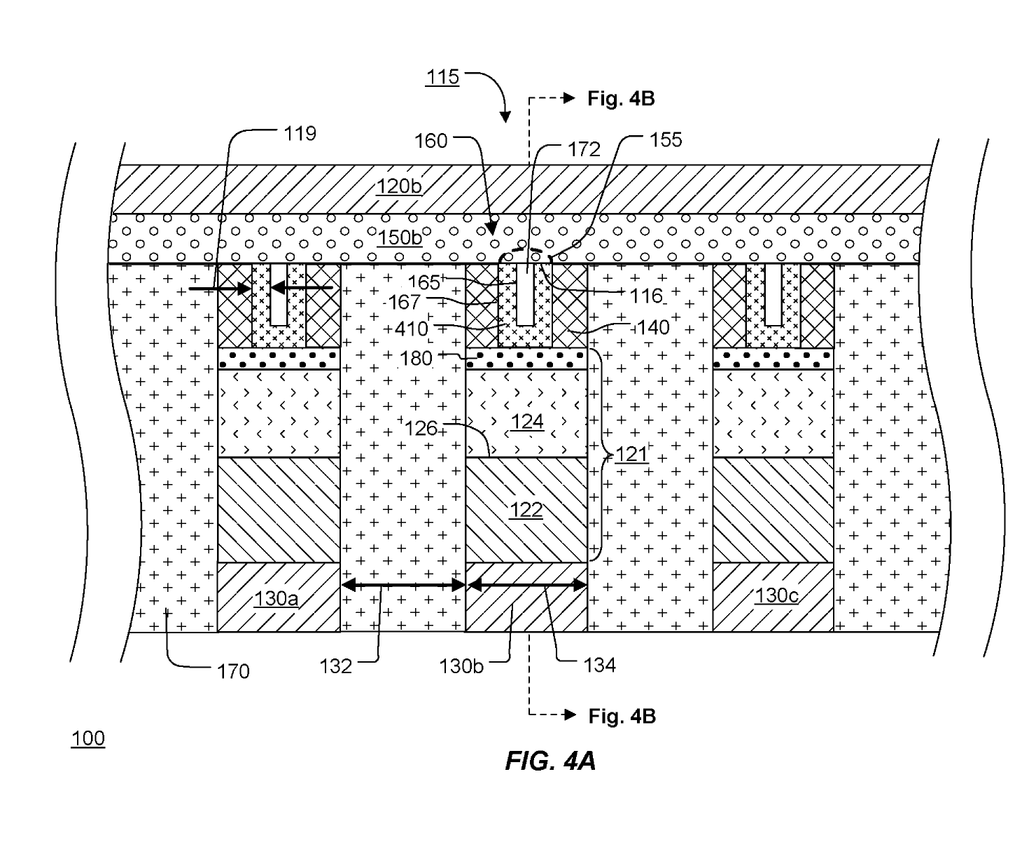

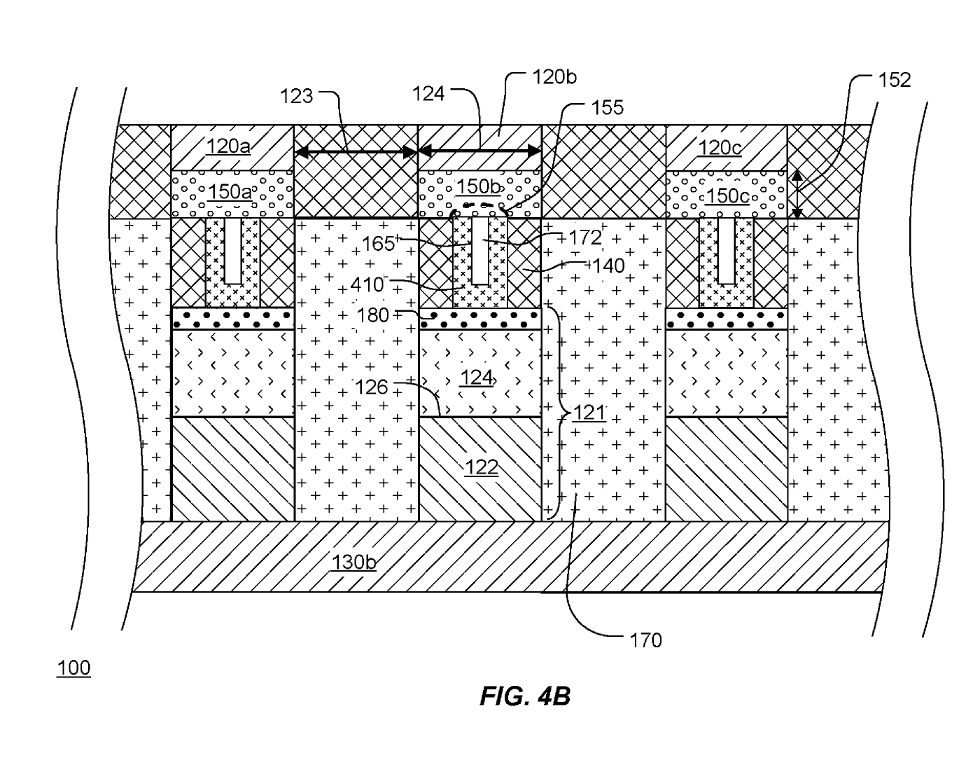

FIGS. 4A and 4B illustrate cross-sectional views of a portion of a third embodiment of memory cells (including representative memory cell 115) arranged in the cross-point array 100, FIG. 4A taken along the bit lines 120 and FIG. 4B taken along the word lines 130.

In the embodiment of FIGS. 4A and 4B, the bottom electrode 410 has an inner surface 165 defining an interior containing fill material 172. In the illustrated embodiment the fill material 172 is an electrically insulating material and may comprise material having a lower thermal conductivity than the material of the bottom electrode 410. In the illustrated embodiment fill material 172 comprises silicon nitride.

The inside surface 165 and outside surface 167 of the bottom electrode 410 define a ring-shaped top surface 116 of the bottom electrode 410 in contact with the strip of memory material 150b. In embodiments, the ring-shaped top surface defined by the outside and inside surfaces 165, 167 has a cross-section that may be circular, elliptical, rectangular or somewhat irregularly shaped, depending on the manufacturing technique applied to form the bottom electrode 410. The “ring-shape” of the top surface 116 described herein, is therefore not necessarily circular, but rather takes the shape of the bottom electrode 410.

As can be appreciated, the active region 155 can be made extremely small in the illustrated structure, thus reducing the magnitude of the current needed to induce a phase change. The thickness 152 of the strips of memory material 150 can be established using thin film deposition techniques. Furthermore, the bottom electrode 410 can be formed using conformal deposition techniques within an opening defined by the dielectric spacer 140, and thus has a thickness 119 preferably less than a minimum feature size for a process, typically a lithographic process, used to form the memory array 100. The small thickness 119 results in a small ring-shaped top surface 116 of the bottom electrode 410 in contact with the memory element 160 of material of strip 150b. The small ring-shape of the bottom electrode 410 concentrates current density in the portion of the memory element 160 near the ring-shaped top surface, thereby reducing the magnitude of the current needed to induce a phase change in the active region 155. Additionally, the fill material 172 and the sidewall spacer 140 preferably comprise material providing some thermal isolation to the active region 155, which also helps to reduce the current necessary to induce a phase change.

In the memory array 100 illustrated in FIGS. 4A-4B, the bottom electrode 410 is self-centered on the diode 121, and the diode is aligned with the underlying word line 130b. As described in more detail with respect to FIGS. 17-19 and 27 below, the material of the sidewall spacer 140 is first patterned during the formation of the diode 121, and the material of the bottom electrode 410 is formed within a subsequently formed opening within the sidewall spacer 140.

FIGS. 5-14 illustrate steps in a fabrication sequence for manufacturing the cross point array 100 of memory cells as illustrated in FIGS. 3A-3B.

FIGS. 5A-5B illustrate top and cross-sectional views of a first step of forming a structure 500. The structure 500 includes a word line material 510 and a diode material 512 on the word line material 510.

The diode material 512 comprises a first doped semiconductor material layer 520, a second doped semiconductor material layer 530, and a conductive cap material layer 540 on the second doped semiconductor material layer 530.

In the illustrated embodiment the word line material 510 comprises doped N⁺ (highly doped N-type) semiconductor material, the first doped semiconductor material layer 520 comprises doped N⁻ (lightly doped N-type) semiconductor material, and the second doped semiconductor material 530 comprises doped P¹ (highly doped P-type) semiconductor material. The layers 510, 520, 530 may be formed by implantation and activation annealing processes as known in the art.

In the illustrated embodiment the conductive cap material layer 540 comprises a silicide containing, for example, Ti, W, Co, Ni, or Ta. In one embodiment the layer 540 comprises cobalt silicide (CoSi) and is formed by depositing a layer of cobalt and performing a rapid thermal process (RTP) such that the cobalt reacts with the silicon of layer 530 to form the layer 540. It is understood that other silicides may also be formed in this manner by depositing titanium, arsenic, doped nickel, or alloys thereof, in a manner similar to the example described herein using cobalt

A first material 550 is on the diode material 512, and a second material 560 is on the first material 560. The layers 550, 560 preferably comprise material which can be selectively processed (e.g. selectively etched) relative to one another. As described in more detail below, layer 550 may comprise conductive bottom electrode material (for example TiN) or may comprise dielectric spacer material (for example SiN) depending upon the manufacturing embodiment used to form the memory cells. In the illustrated embodiment the layer 560 comprises amorphous silicon

In the illustrated embodiment the layers 510, 520, and 530 have a total thickness 515 of about 300 nm, layer 540 has a thickness 545 of about 20 nm, layer 550 has a thickness 555 of about 100 nm, and layer 560 has a thickness 565 of about 100 nm.

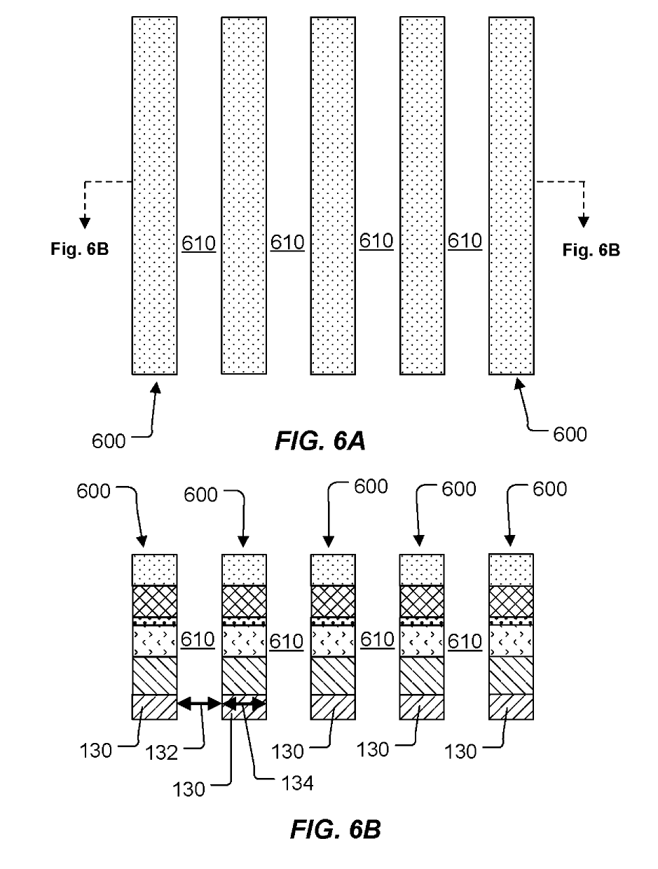

Next, the structure 500 is patterned to form a plurality first trenches 610 extending in a first direction to define a plurality of strips 600, each strip including word lines 130 comprising word line material of layer 510, resulting in the structure illustrated in top and cross-sectional views of FIGS. 6A and 6B respectively. The word lines 130 have width 134 and a separation distance 132, each preferably equal to the minimum feature size of a process, such as a lithographic process, used to form the first trenches 610.

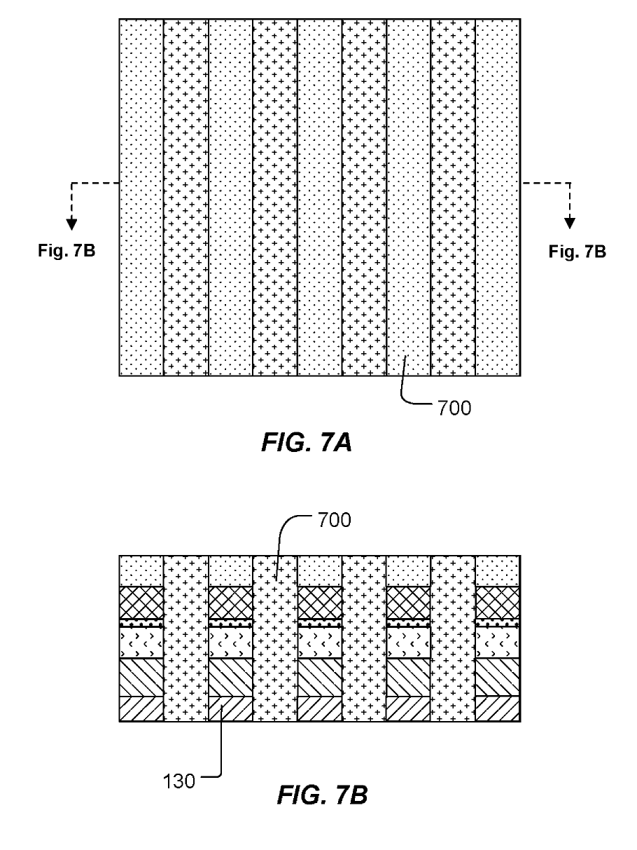

Next, the trenches 610 of the structure illustrated in FIGS. 6A-6B are filled with a dielectric fill material 700, resulting in the structure illustrated in the top and cross-sectional views of FIGS. 7A and 7B respectively. The dielectric fill material 700 may comprise, for example silicon dioxide, and may be formed by depositing the material 700 within the trenches 610 and then performing a planarizing process such as chemical mechanical polishing CMP.

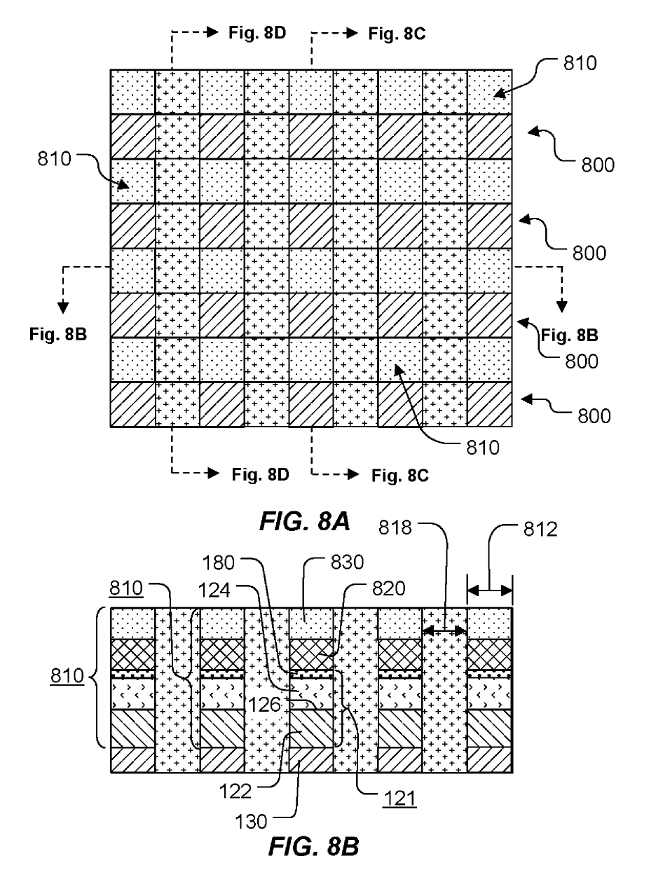

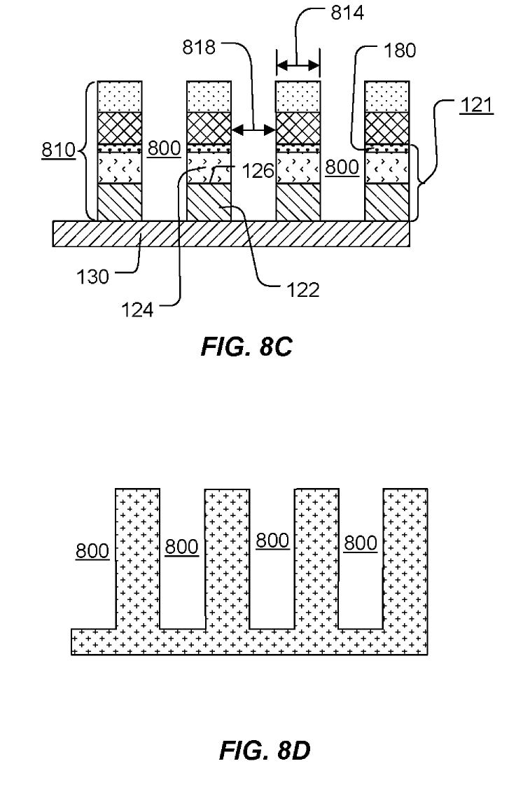

Next, the structure illustrated in FIGS. 7A-7B is patterned to form a plurality of second trenches 800 extending in parallel in a second direction to define a plurality of stacks 810, resulting in the structure illustrated in the top view of FIG. 8A and the cross-sectional views of FIGS. 8B-8D respectively. The trenches 800 and stacks 810 may be formed by patterning a layer of photoresist on the structure illustrated in FIGS. 7A-7B, and etching down to the word lines 130 using the patterned photoresist as an etch mask.

As can be seen in the cross-sectional views of FIGS. 8B and 8C, each of the stacks 810 includes a diode 121 comprising diode material on the corresponding word line 130, a first element 820 comprising first material of layer 550 on the diode 121, and a second element 830 comprising second material of layer 560 on the first element 820.

The diodes 121 include a first doped semiconductor region 122 comprising material from layer 520 and a second doped semiconductor region 124 comprising material from layer 530. The first doped semiconductor region 122 and the second doped semiconductor region 124 define a pn junction 126 therebetween.

Due to the formation of the first trenches 610 of FIGS. 6A-6B to form the strips 600 including word lines 130 and the subsequent formation of the second trenches 800 of FIGS. 8A-8D, the stacks 810 are self-aligned to the corresponding underlying word lines 130. Additionally, the stacks 810 have widths 812, 814 and separation distances 816, 818 both preferably equal to the minimum feature size of the process (typically a lithographic process) used to form the trenches 610 and 810.

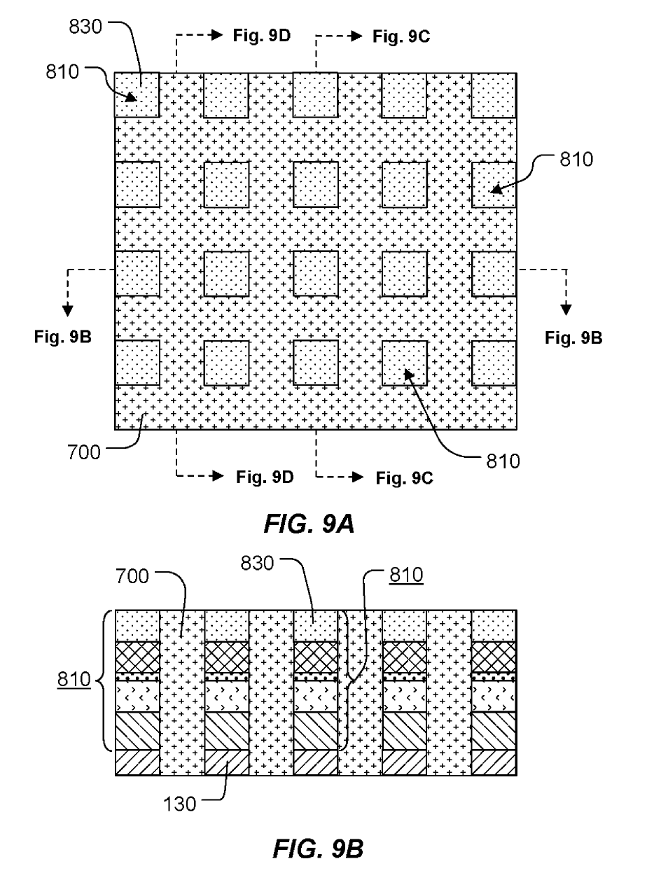

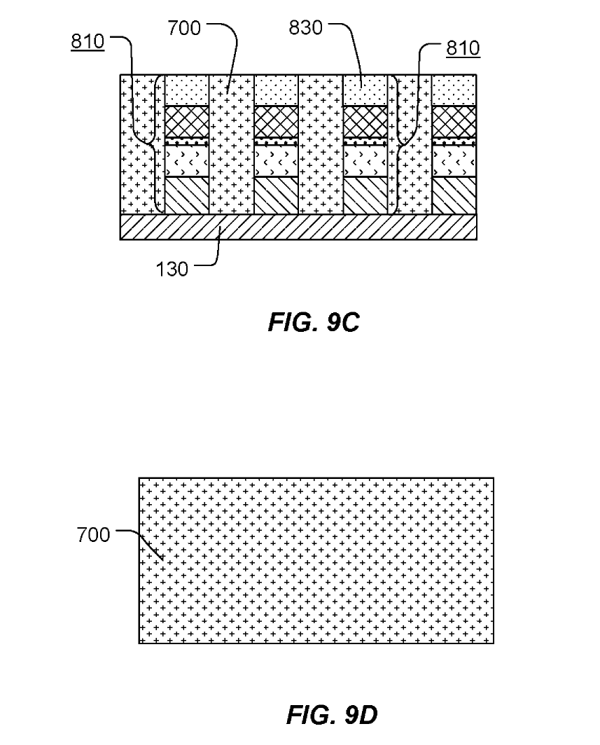

Next, the trenches 800 of the structure illustrated in FIGS. 8A-8D are filled with additional dielectric fill material 700, resulting in the structure illustrated in the top view of FIG. 9A and the cross-sectional views of FIGS. 9B-9D respectively. In the illustrated embodiment the trenches 800 are filled with the same material at that of dielectric 700 used to fill the trenches 610 as described above with reference to FIGS. 7A-7B. The dielectric fill material 700 may be formed by depositing the material within the trenches 800 and then performing a planarizing process such as chemical mechanical polishing CMP to expose the top surface of the second elements 830. In embodiments in which the trenches 800 are formed using a mask of patterned photoresist, the planarizing process (such as CMP) can be used to remove the patterned photoresist mask.

Next, dielectric fill material 700 of the first and second trenches 610, 800 are removed to expose sidewall surfaces 1000 of the second elements 830, resulting in the structure illustrated in the top view of FIG. 10A and the cross-sectional views of FIGS. 10B-10C.

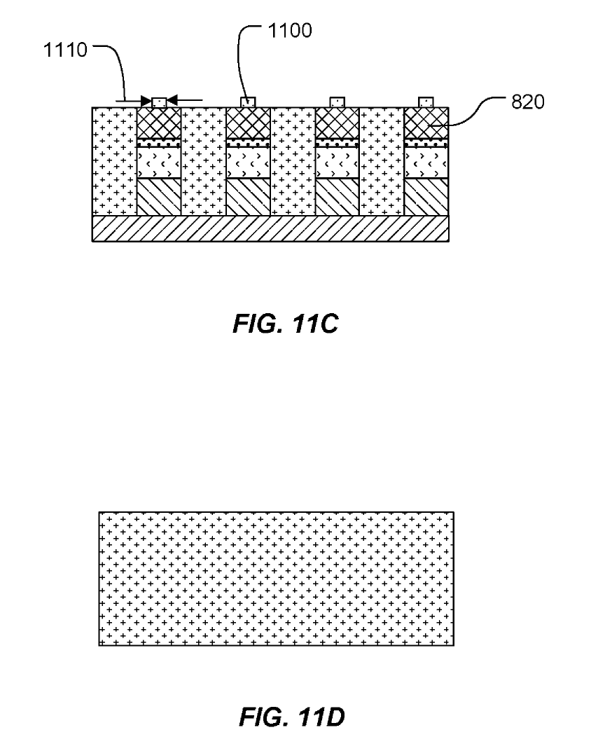

Next the second elements 830 of FIGS. 10A-10D are trimmed to a reduced width, thereby forming trimmed elements 1100 having a width 1110 as shown in the structure illustrated in the top view of FIG. 11A and the cross-sectional views of FIGS. 11B-11D. In the illustrated embodiment an isotropic etching process is used to reduce the thickness and width of second elements 830 to form the trimmed elements 1100. In the illustrated embodiment the second elements 830 comprise amorphous silicon and may be isotropically etched using, for example, a KOH wet etch process or tetramethylammonium hydroxide (THMA). Alternatively, RIE can be applied to a variety of materials to trim the elements 830. As can be seen in the Figures, the trimmed elements 1100 have a width 1110 less than that of the diodes 121 of stacks 810 and cover only a portion of the first elements 820. Since the diodes 121 preferably have a width equal to than the minimum feature size of the process used to form the diodes 121, the width 1110 can be less than the minimum feature size. In one embodiment the width 1110 of the trimmed elements 1100 is about 30 nm.

In the Figures the trimmed elements 1100 have a square-like cross-section. However, in embodiments the trimmed elements 1100 may have a cross-section that is circular, elliptical, rectangular or somewhat irregularly shaped, depending on the manufacturing technique applied to form the trimmed elements 1100.

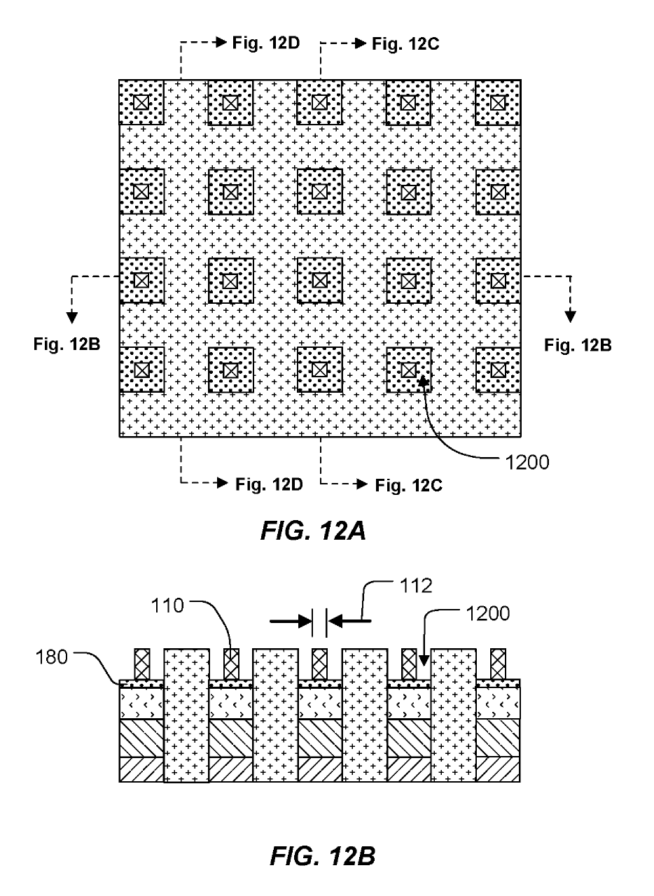

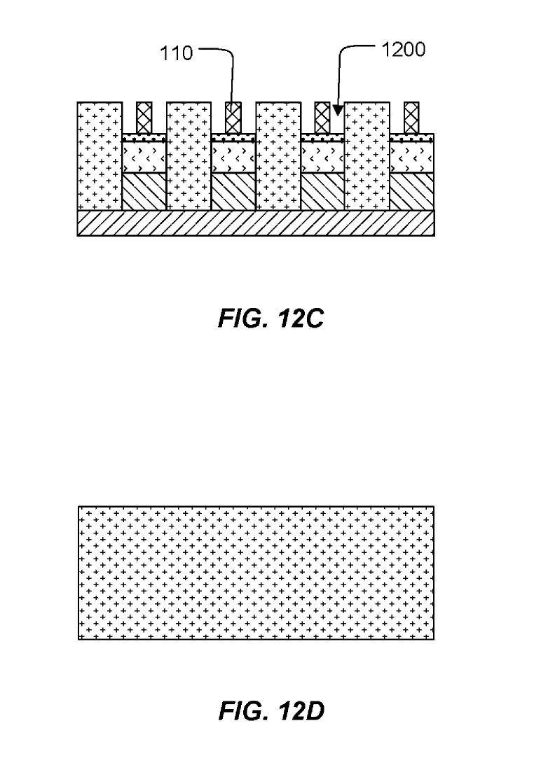

Next, etching is performed on the first elements 820 using the trimmed elements 1100 as a mask to form bottom electrodes 110 and openings 1200 surrounding the bottom electrodes 110. The trimmed elements 1110 are then removed, resulting in the structure illustrated in the top view of FIG. 12A and the cross-sectional views of FIGS. 12B-12D.

As can be seen in the Figures the openings 1200 extend to the conductive caps 180, the conductive caps 180 acting as an etch stop layer during the formation of the openings 1200.

In FIGS. 12A-12D the bottom electrodes 110 have a square-like cross-section. However, in embodiments the bottom electrodes 110 may have a cross-section that is circular, elliptical, rectangular or somewhat irregularly shaped, depending on the manufacturing technique applied to form the trimmed elements 1100 and the bottom electrodes 110.

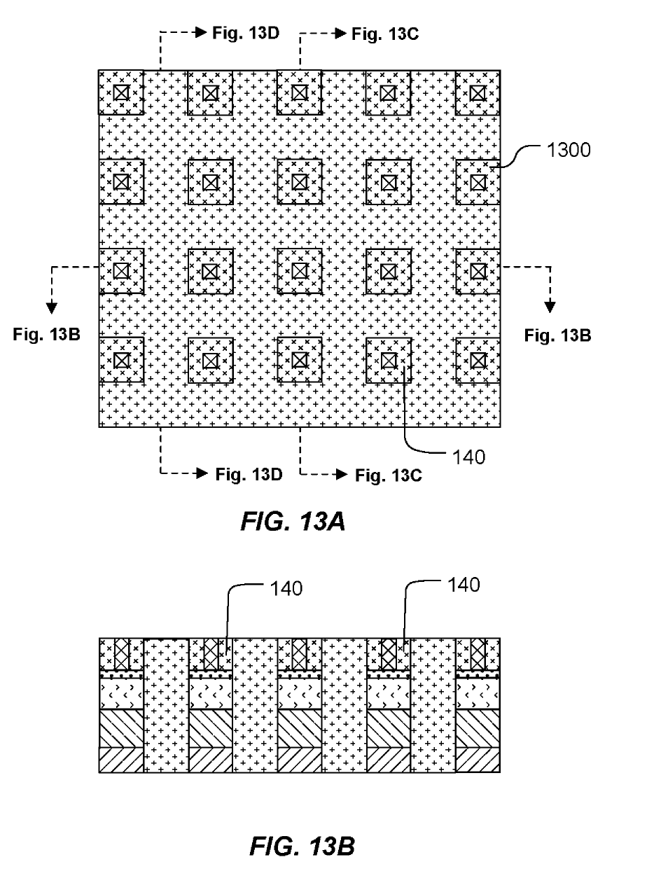

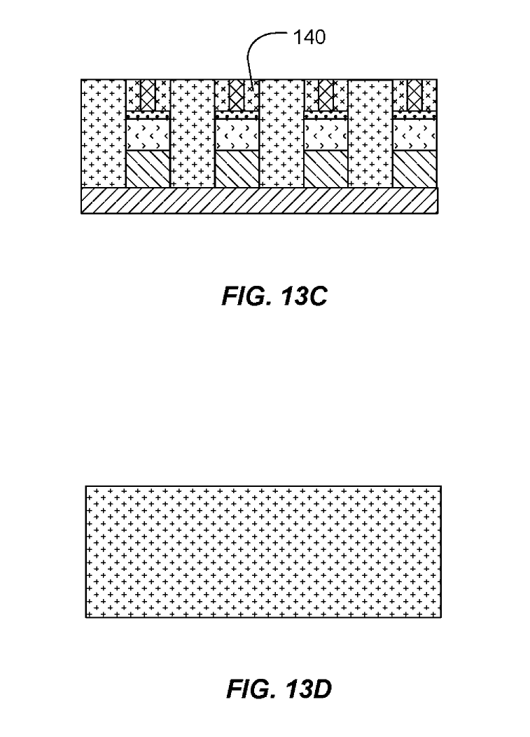

Next, dielectric spacers 140 are formed within the openings 1200 of FIGS. 12A-12D, resulting in the structure illustrated in the top view of FIG. 13A and the cross-sectional views of FIGS. 13B-13D. In the illustrated embodiment the dielectric spacers 140 comprise SiON and are formed by depositing dielectric spacer material on the structure of FIGS. 12A-12D followed by a planarizing process such as CMP.

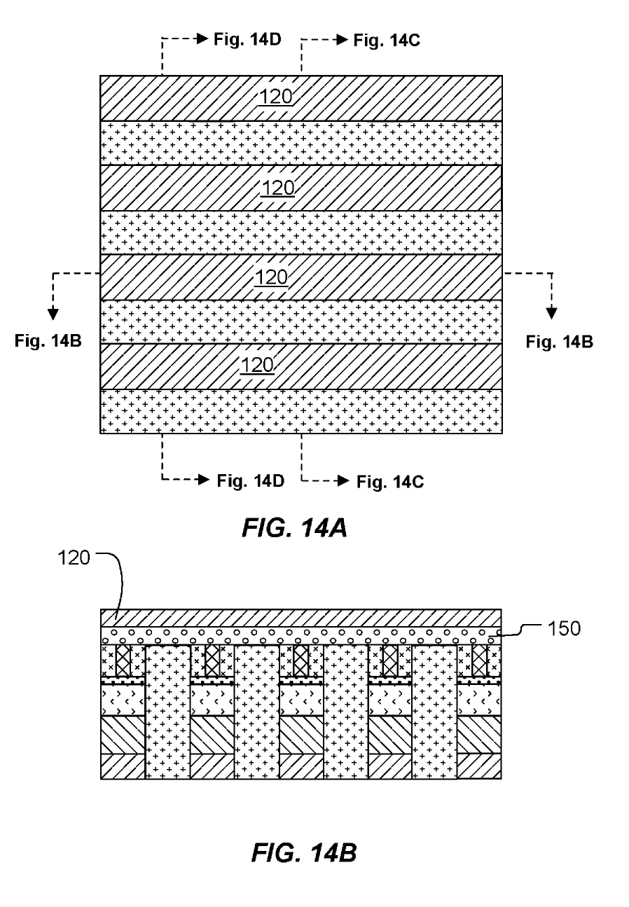

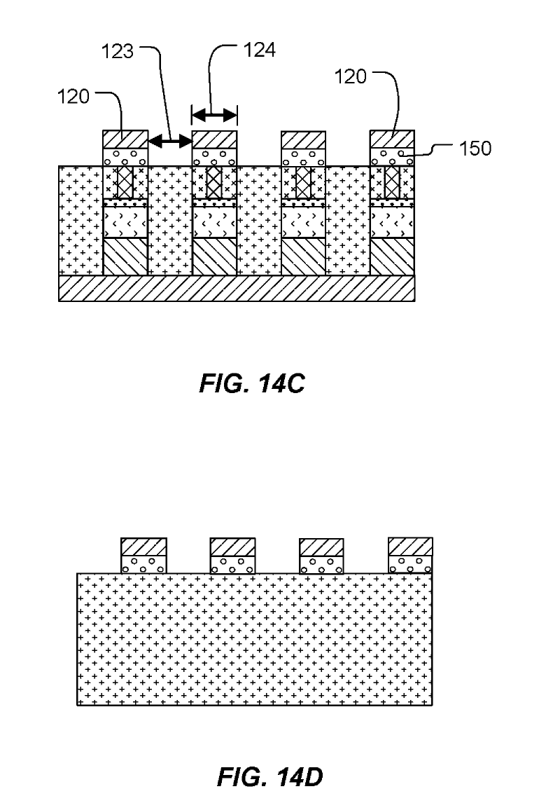

Next, a plurality of memory material strips 150 and bit lines 120 overlying corresponding memory material strips 150 are formed on the structure illustrated in FIGS. 13A-13D, resulting in the structure illustrated in the top view of FIG. 14A and the cross-sectional views of FIGS. 14B-14D. The strips 150 and bit lines 120 may be formed by forming memory material on the structure illustrated in FIGS. 13A-13D, forming bit line material on the memory material, patterning a layer of photoresist on the bit line material, and then etching the bit line material and the memory material using the patterned photoresist as an etch mask.

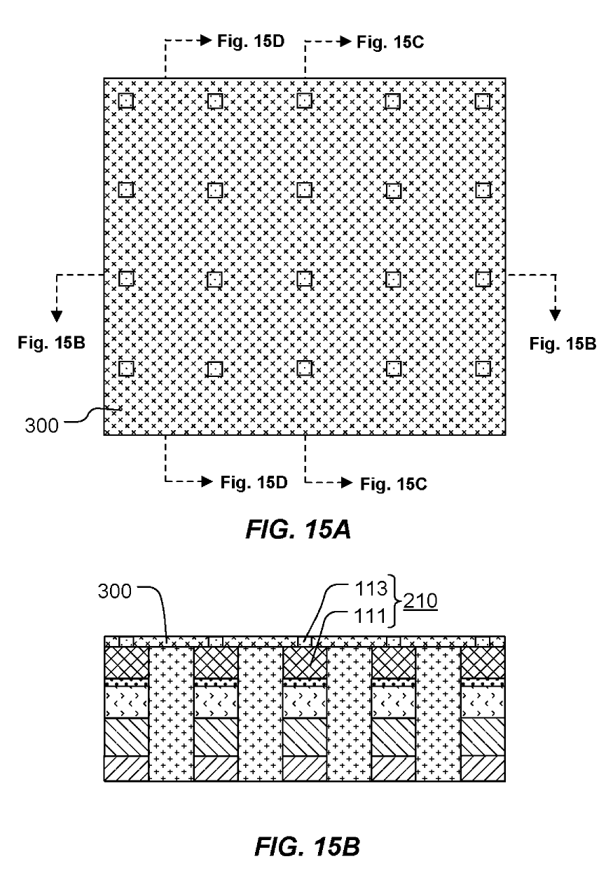

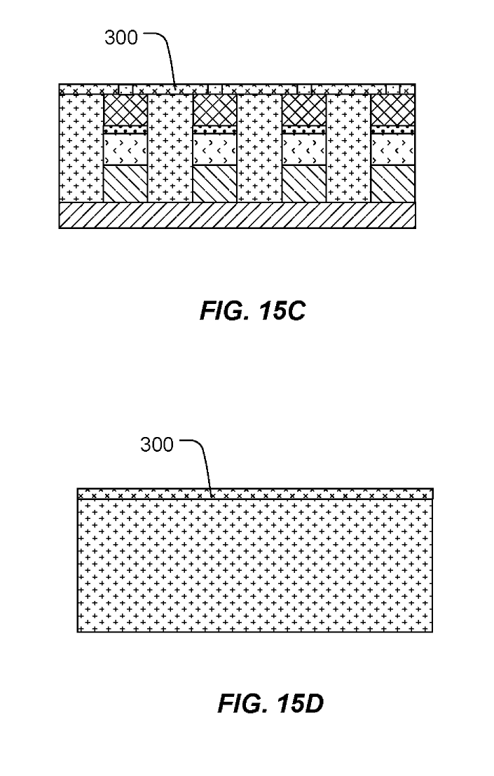

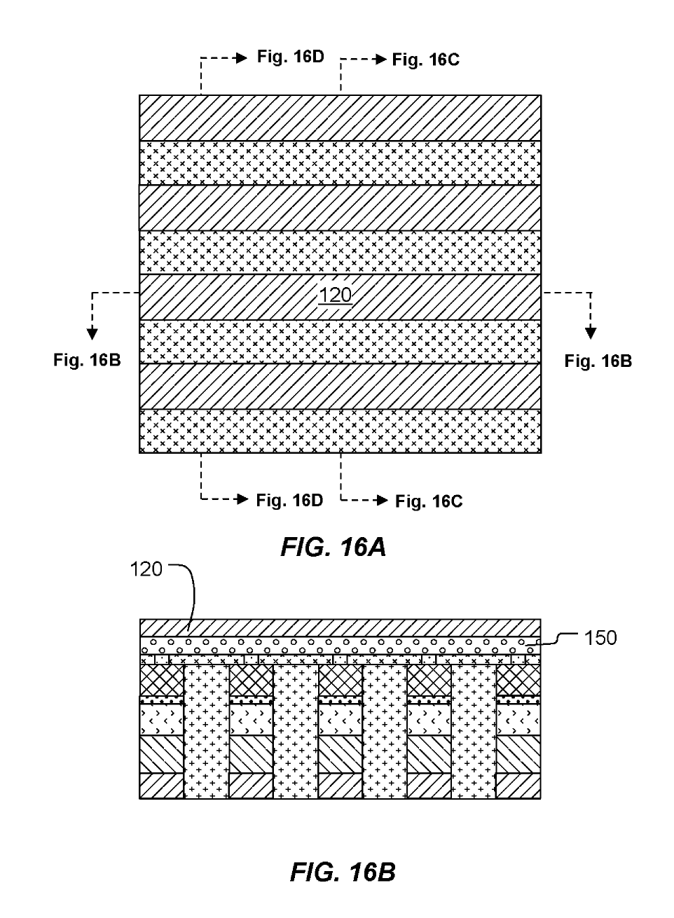

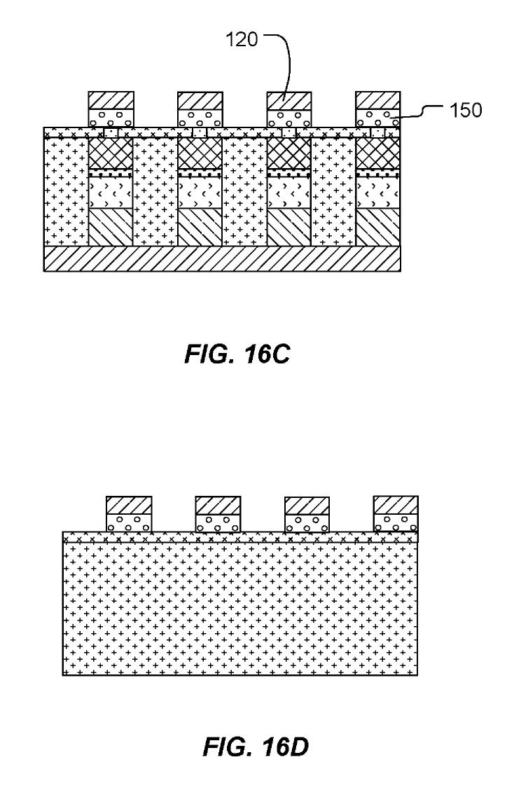

FIGS. 15-16 illustrate an alternative manufacturing embodiment to that illustrated in FIGS. 12-13, resulting in memory cells as illustrated in FIGS. 3A-3B.

Dielectric layer 300 is formed on the structure illustrated in FIGS. 11A-11D to surround the trimmed second elements 1100, resulting in the structure illustrated in the top view of FIG. 15A and the cross-sectional views of FIGS. 15B-15D. The trimmed second elements 1100 of FIG. 11 are the second conductive elements 113 of the bottom electrodes 210, and the elements 820 are the first conductive elements 111 of the bottom electrodes 210.

Next, a plurality of memory material strips 150 and bit lines 120 overlying corresponding memory material strips 150 are formed on the structure illustrated in FIGS. 15A-15D, resulting in the structure illustrated in FIGS. 16A-16D. The strips 150 and bit lines 120 may be formed by forming memory material on the structure illustrated in FIGS. 15A-15D, forming bit line material on the memory material, patterning a layer of photoresist on the bit line material, and then etching the bit line material and the memory material using the patterned photoresist as an etch mask.

FIGS. 17-24 illustrate an alternative manufacturing embodiment to that illustrated in FIGS. 10-14.

The second elements 830 of the stacks 810 of FIGS. 9A-9D are removed to form vias 1700 exposing the first elements 820, resulting in the structure illustrated in top view of FIG. 17A and the cross-sectional views of FIGS. 17B-17D. In the illustrated embodiment the second elements 830 comprise amorphous silicon and may be removed by etching using, for example, KOH or THMA.

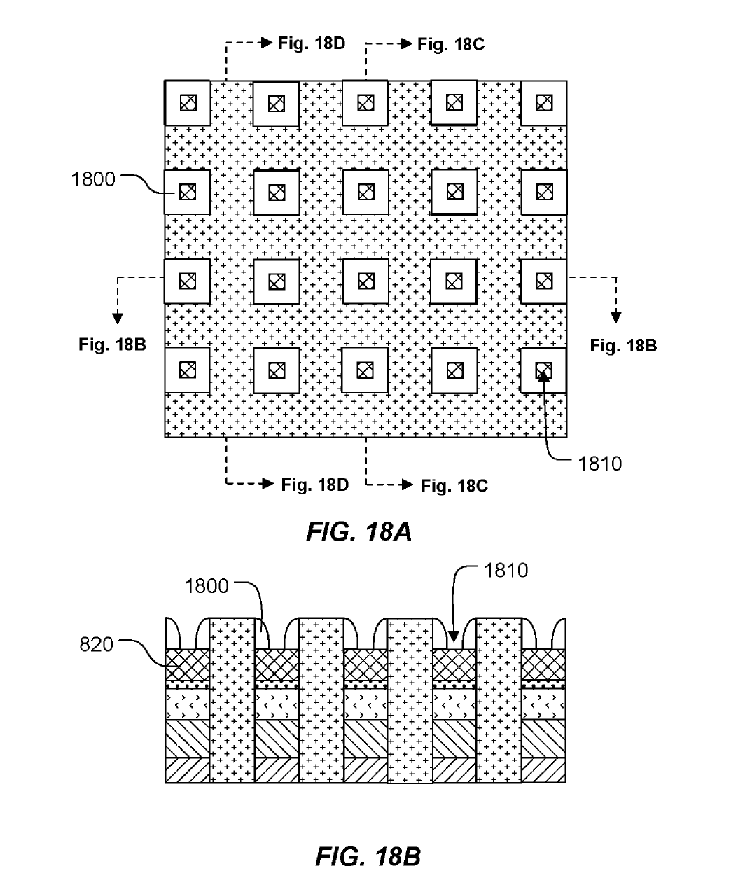

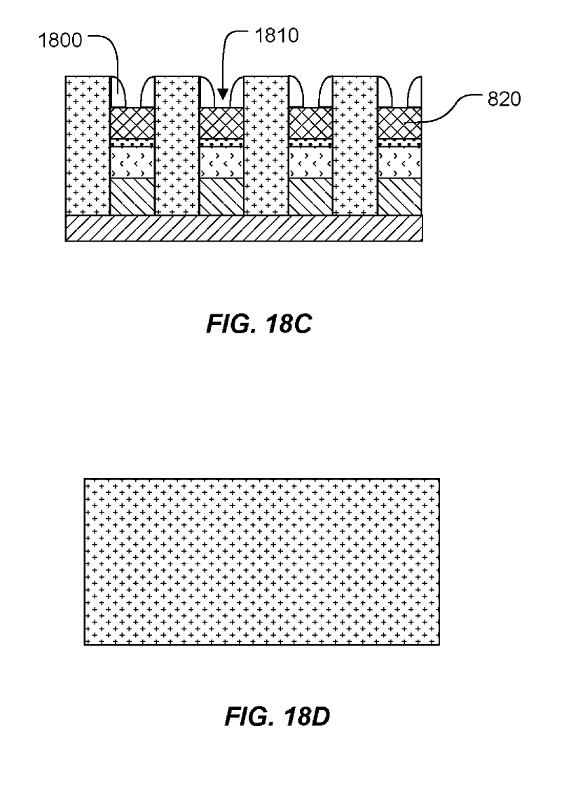

Next, sidewall spacers 1800 are formed within the vias 1700 of FIGS. 17A-17D, resulting in the structure illustrated in the top view of FIG. 18A and the cross-sectional views of FIGS. 18B-18D. The sidewall spacers 1800 define openings 1810 within the vias 1700, and in the illustrated embodiment the sidewall spacers 1800 comprise silicon.

The sidewall spacers 1800 may be formed by forming a conformal dielectric material layer on the structure illustrated in FIGS. 17A-17D, and anisotropically etching the conformal dielectric material layer to expose a portion of the first elements 820.

In the illustrated embodiment the sidewall spacers 1800 define openings 1810 having a square-like cross-section. However, in embodiments the openings 1810 may have a cross-section that is circular, elliptical, rectangular or somewhat irregularly shaped, depending on the manufacturing technique applied to form the sidewall spacers 1800.

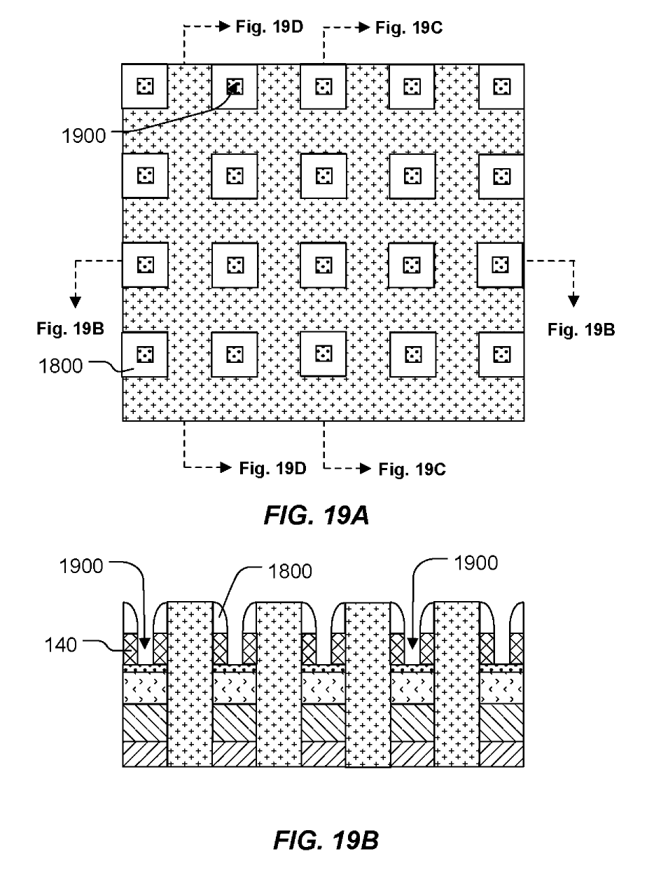

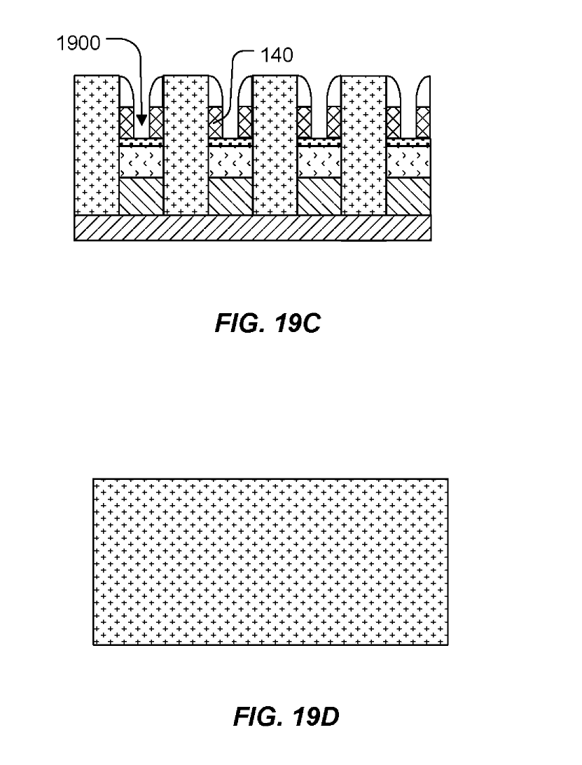

Next, the first elements 820 are etched to form dielectric spacers 140 using the sidewall spacers 1800 as an etch mask, resulting in the structure illustrated in the top view of FIG. 19A and the cross-sectional views of FIGS. 19B-19D.

As can be seen in the FIGS. 19A-19D the dielectric spacers 140 have openings 1900 extending to the conductive caps 180, the conductive caps 180 acting as an etch stop layer during the formation of the dielectric spacers 140.

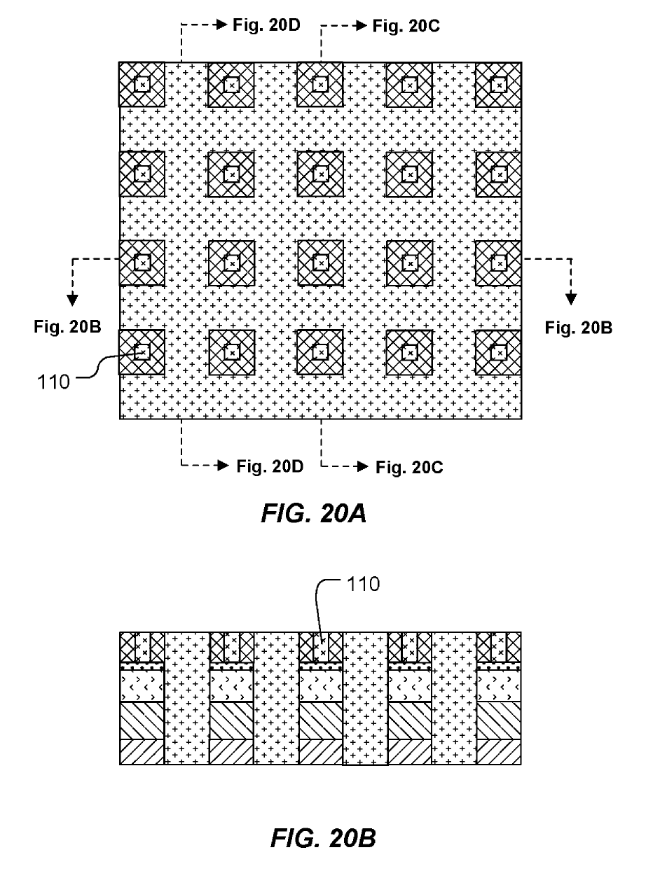

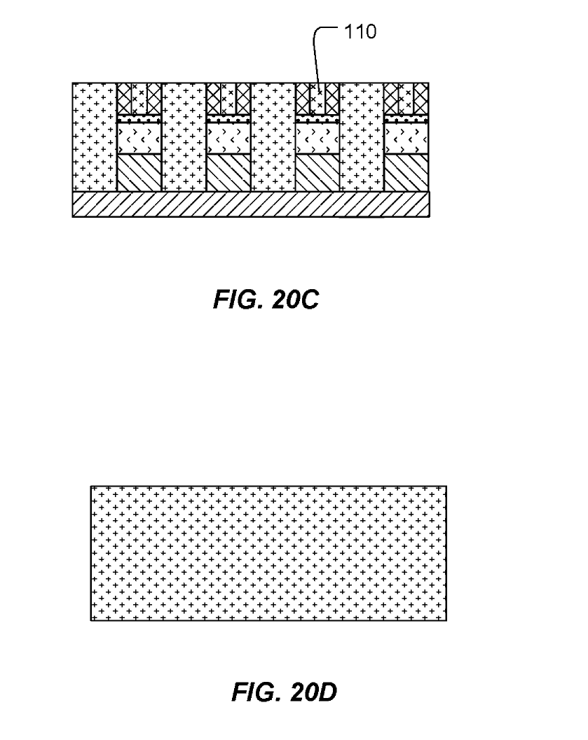

Next, bottom electrode material is formed within the openings 1900 defined by the dielectric spacers 140 and a planarizing process (for example CMP) is performed to remove the sidewall spacers 1800, thereby forming bottom electrodes 110 self-centered on the diode 121 as illustrated in the top view of FIG. 20A and the cross-sectional views of FIGS. 20B-20D. The bottom electrode material may comprise, for example, TiN or TaN.

In the illustrated embodiment the bottom electrodes 110 have a square-like cross-section. However, in embodiments the bottom electrodes 110 may have a cross-section that is circular, elliptical, rectangular or somewhat irregularly shaped, depending on the manufacturing technique applied to form the sidewall spacers 1800 and openings 1900.

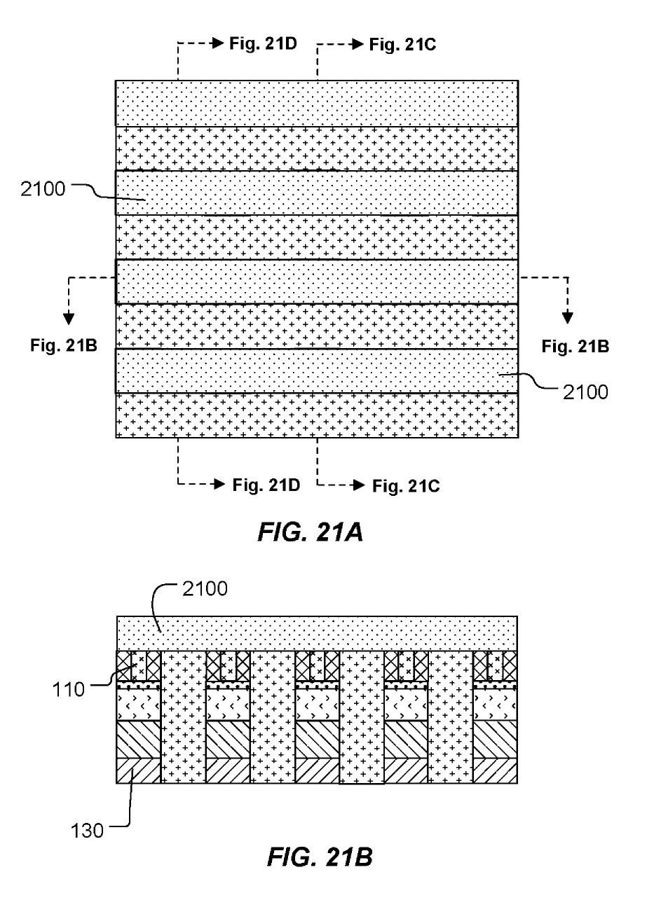

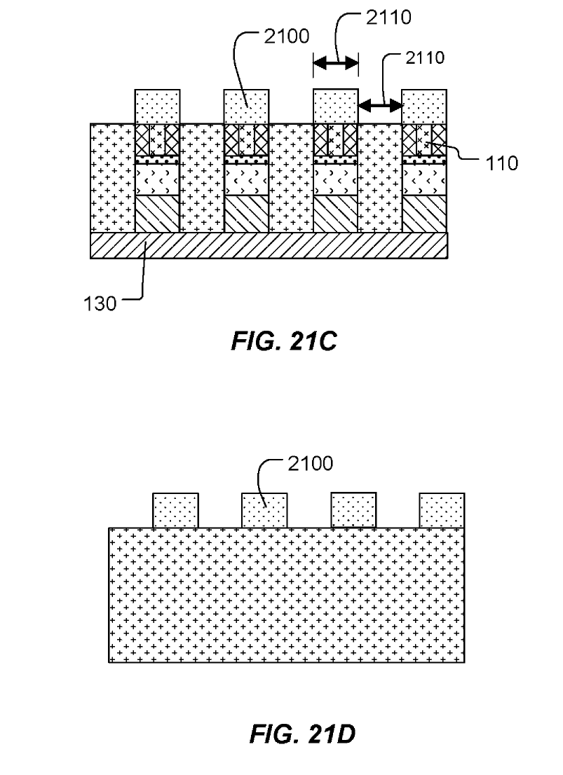

Next, sacrificial material strips 2100 extending in the second direction are formed on the structure illustrated in FIGS. 20A-20D, resulting in the structure illustrated in the top view of FIG. 21A and the cross-sectional views of FIGS. 21A-21B. The sacrificial material strips 2100 extend in parallel in the second direction and have a width 2100 and a separation distance 2110, the strips 2100 each contacting the top surfaces of a plurality of bottom electrodes 110. In the illustrated embodiment the strips 2100 comprise amorphous silicon. The strips may be formed by forming a layer of material on the structure illustrated in FIGS. 20A-20D, and patterning the layer of material to form the strips 2100 using a lithographic process.

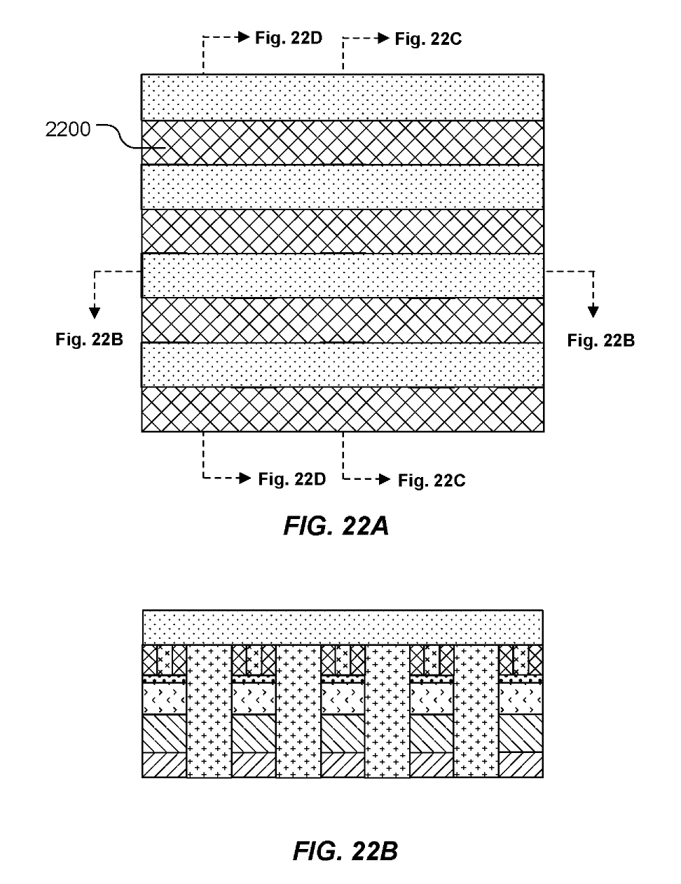

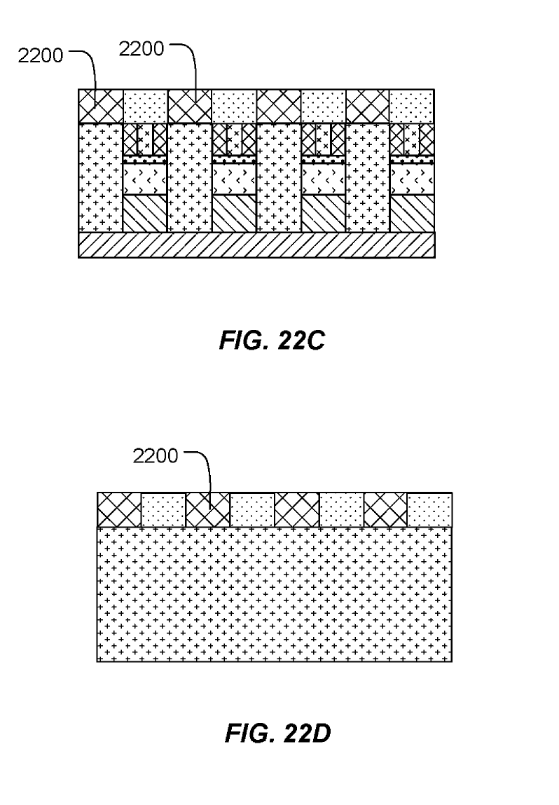

Next, dielectric strips 2200 is formed between the sacrificial material strips 2100, resulting in the structure illustrated in the top view of FIGS. 22A and the top and cross-sectional views of FIGS. 22B-22D. The dielectric strips 2200 can be formed by depositing dielectric material on the structure illustrated in FIGS. 21A-21D, followed by a planarizing process (for example CMP) to expose the top surface of the sacrificial material strips 2100. In the illustrated embodiment the dielectric 2200 comprises SiN.

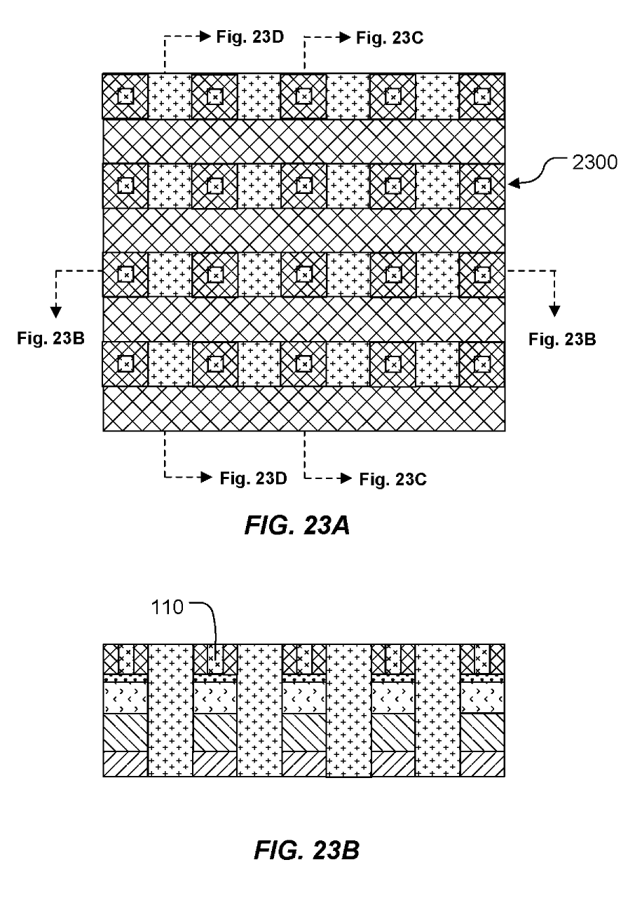

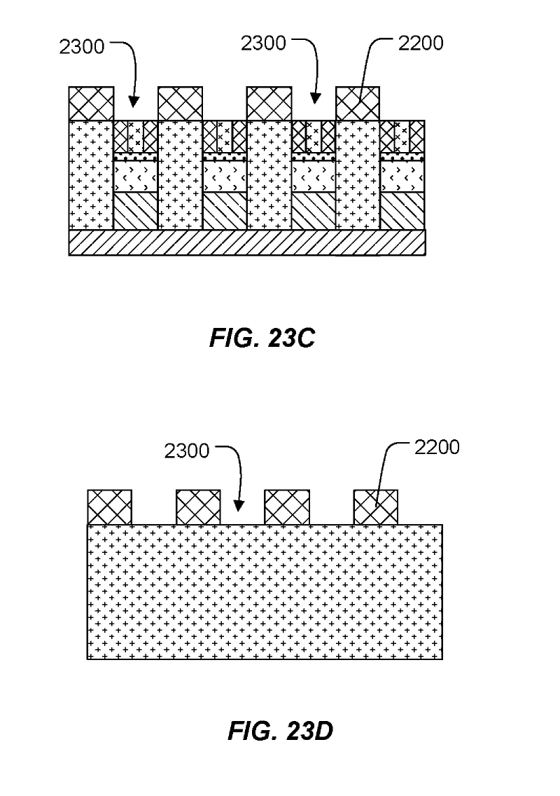

Next, the sacrificial material strips 2100 are removed expose the top surfaces of the bottom electrodes 110 and define trenches 2300 between the dielectric strips 2200, resulting in the structure illustrated in the top view of FIG. 23A and the cross-sectional views of FIGS. 23B-23D. In the illustrated embodiment the strips 2100 comprise amorphous silicon and may be removed by etching using, for example, KOH or THMA.

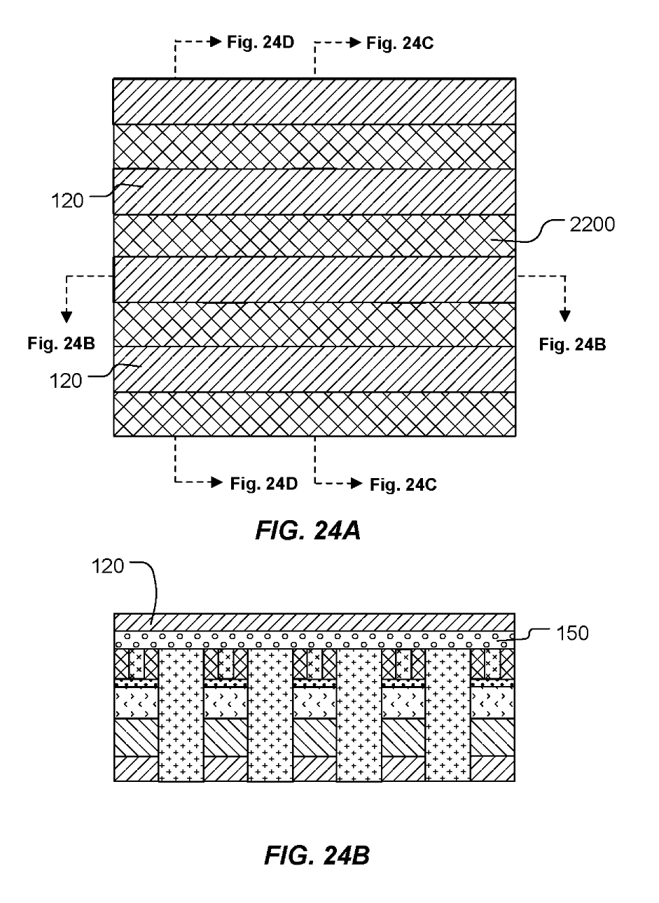

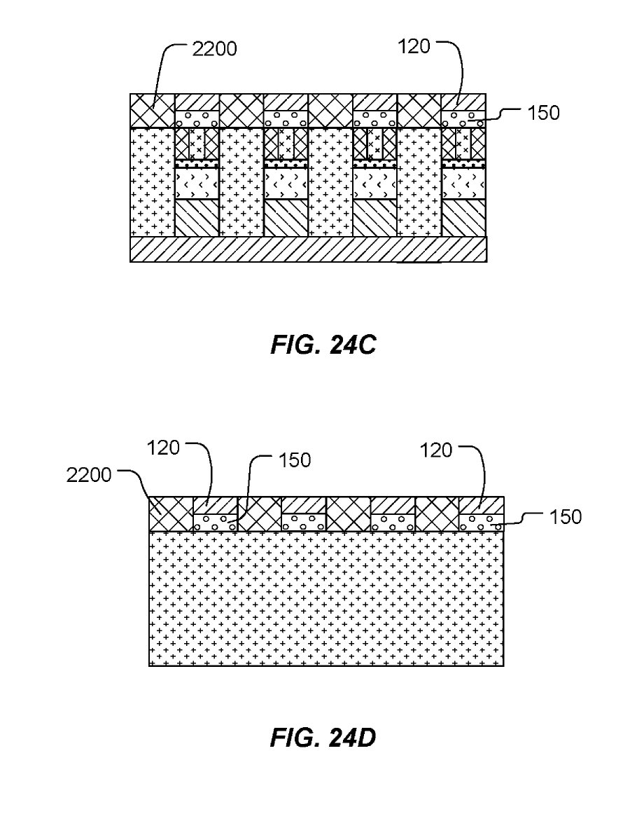

Next, memory material strips 150 and bit lines 120 overlying corresponding memory material strips 150 are formed within the trenches 2300, resulting in the structure illustrated in the top view of FIG. 24A and the cross-sectional views of FIGS. 24B-24D. The memory material strips 150 and bit lines 120 can be formed by depositing memory material using CVD or PVD on the structure illustrated in FIGS. 23A-23D, performing a planarization process such as CMP, etching back the memory material using for example Reactive Ion Etching to form the strips 150, and forming bit line material to fill the trenches 2300 and form the bit lines 120.

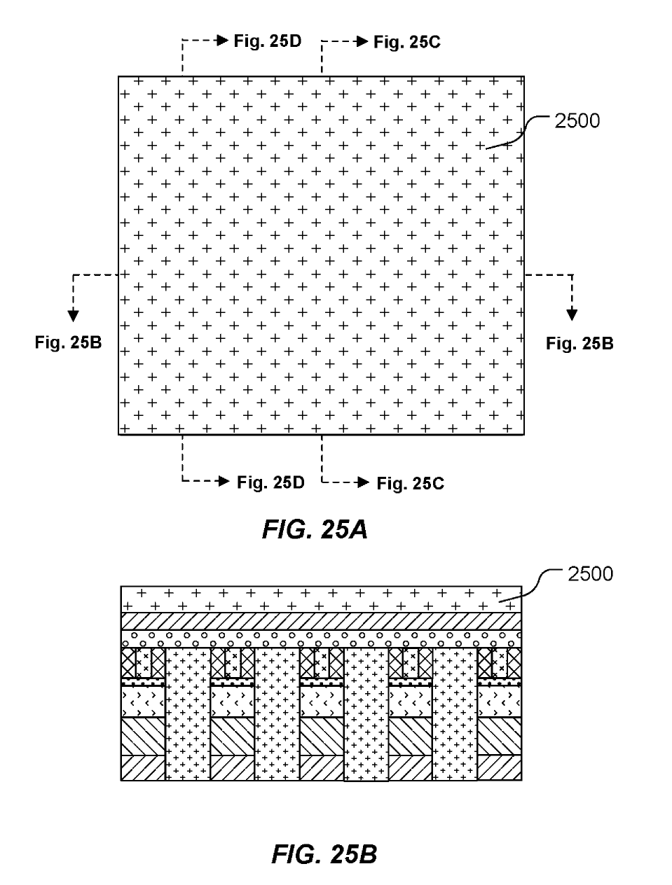

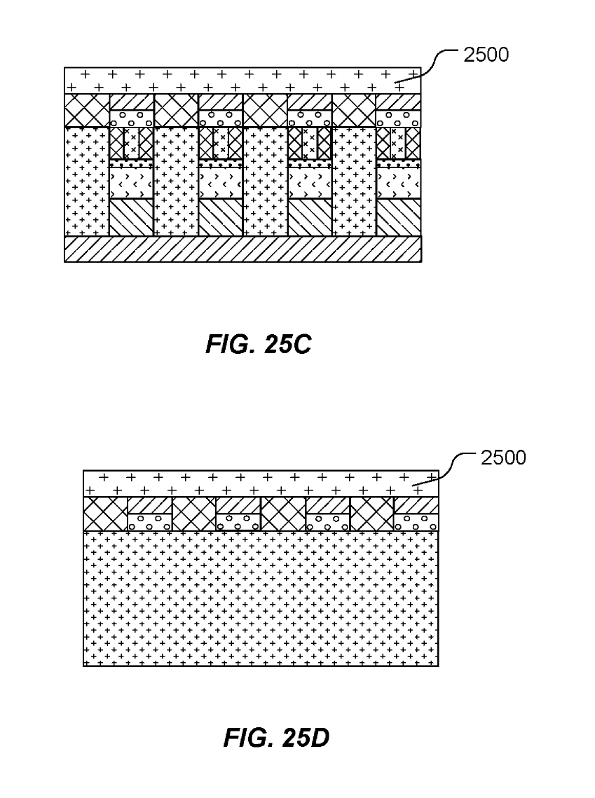

Next, an oxide layer 2500 is formed on the structure illustrated in FIGS. 24A-24D, resulting in the structure illustrated in the top view of FIG. 25A and the cross-sectional views of FIGS. 25B-25D.

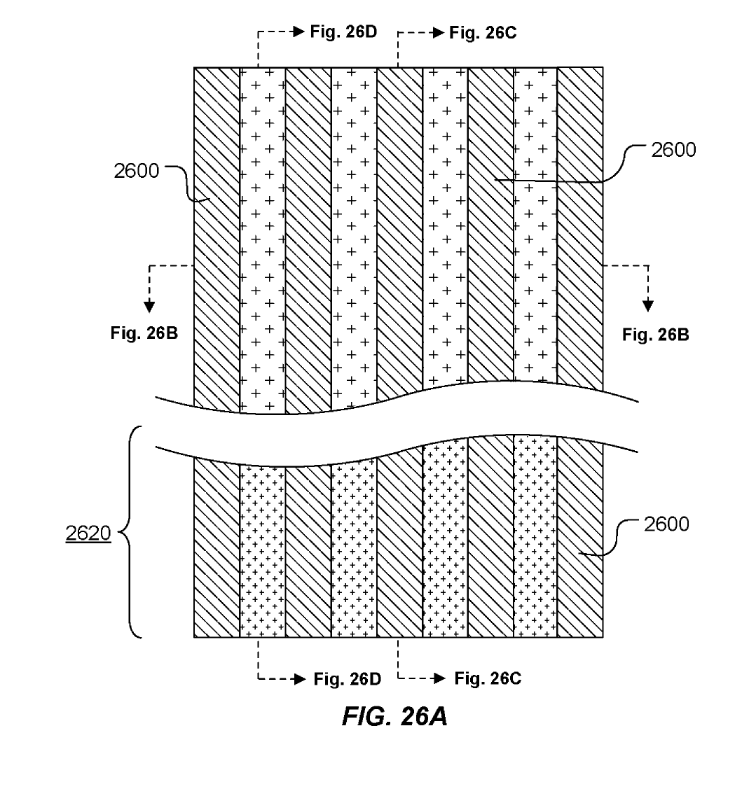

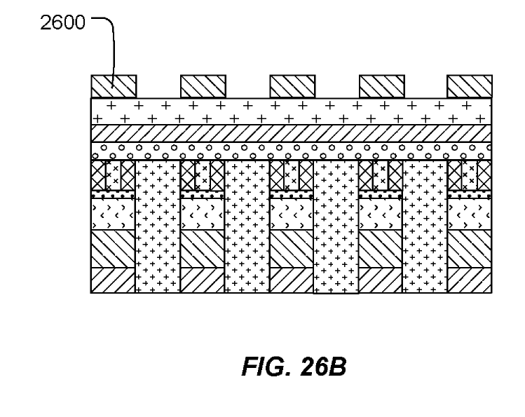

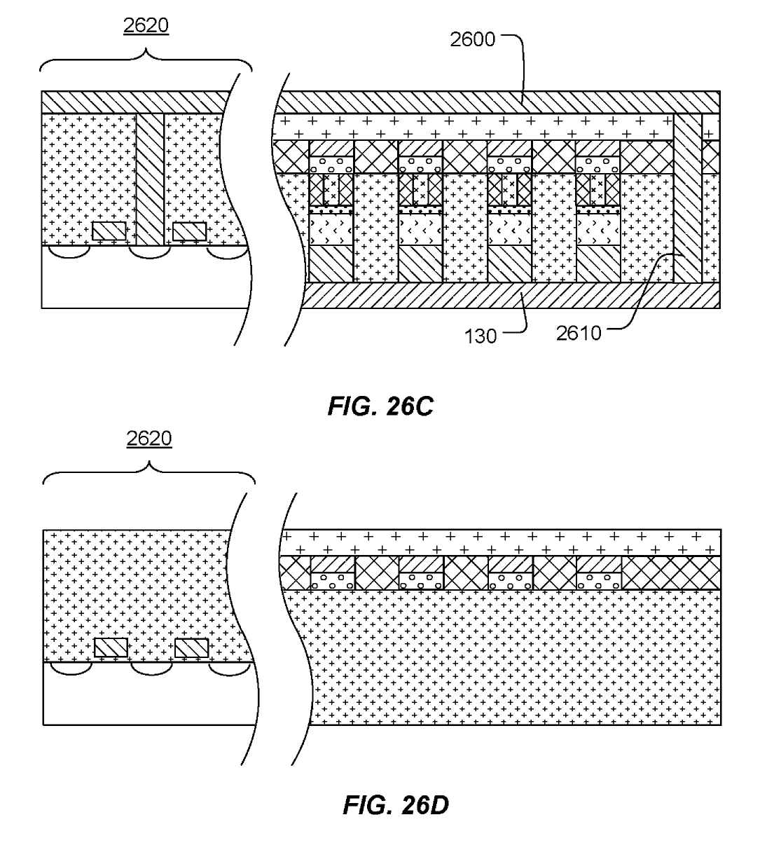

Next, an array of conductive vias 2610 are formed extending through the oxide layer 2500 to contact a corresponding word line 130, and global word lines 2600 are formed on the oxide layer and in contact with a corresponding conductive via 2610 in the array of conductive vias 2610, resulting in the structure illustrated in FIGS. 26A-26D.

The global word lines 2600 extend to peripheral circuitry 2620 including CMOS devices as shown in the top view of FIG. 26A and the cross-sectional views of FIGS. 26C-26D.

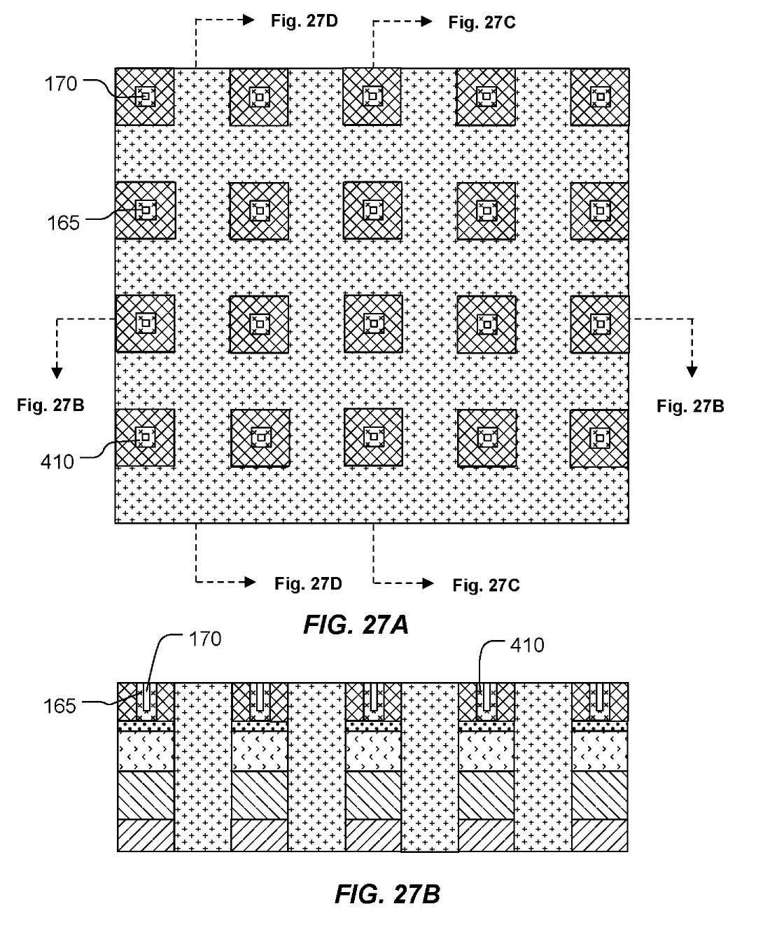

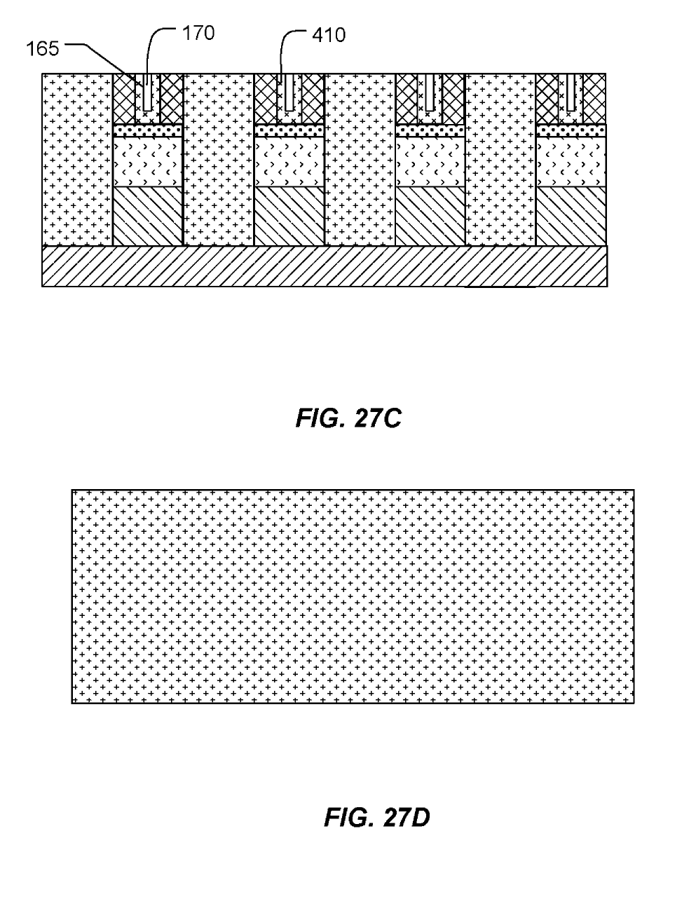

FIG. 27 illustrates an alternative embodiment to that of FIG. 20 for forming the bottom electrode, illustrating the formation of the bottom electrode 410 having a ring-shape top surface.

In FIG. 27, a bottom electrode material is formed on the structure illustrated in FIGS. 19A-19D including within the openings 1900 defined by the dielectric spacers 140 using a process that does not completely fill the openings 1900. A fill material 172 is then formed on the bottom electrode material to fill the openings and the structure is planarized (for example using CMP), thereby forming the bottom electrodes 410 as illustrated in FIGS. 27A-27D. Each bottom electrode 410 has an inner surface 165 defining an interior containing fill material 172.

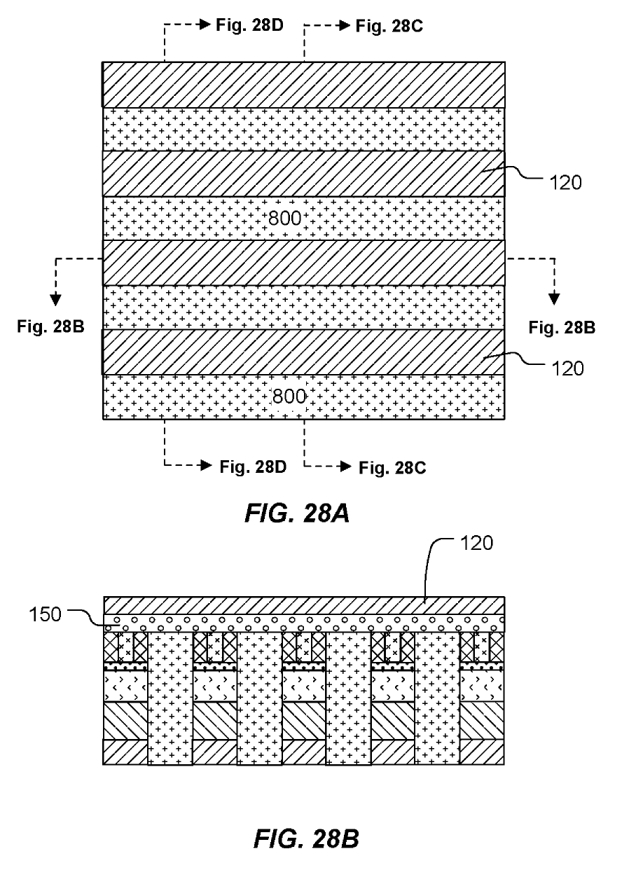

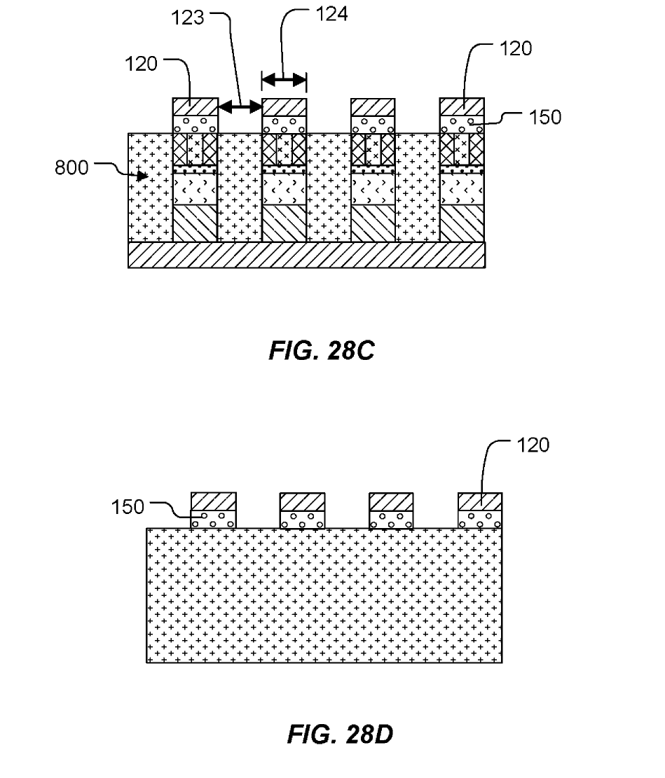

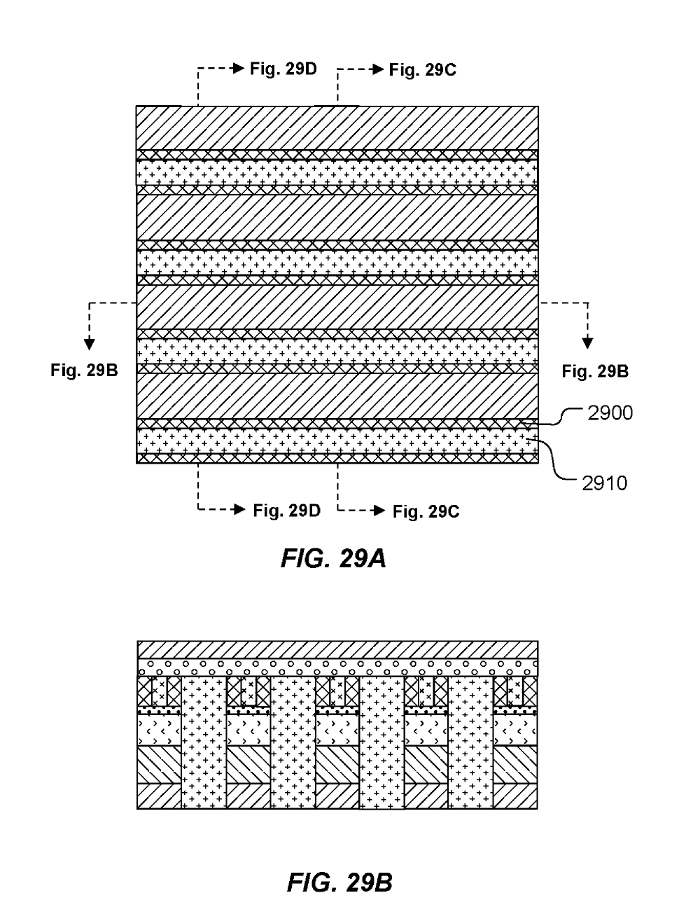

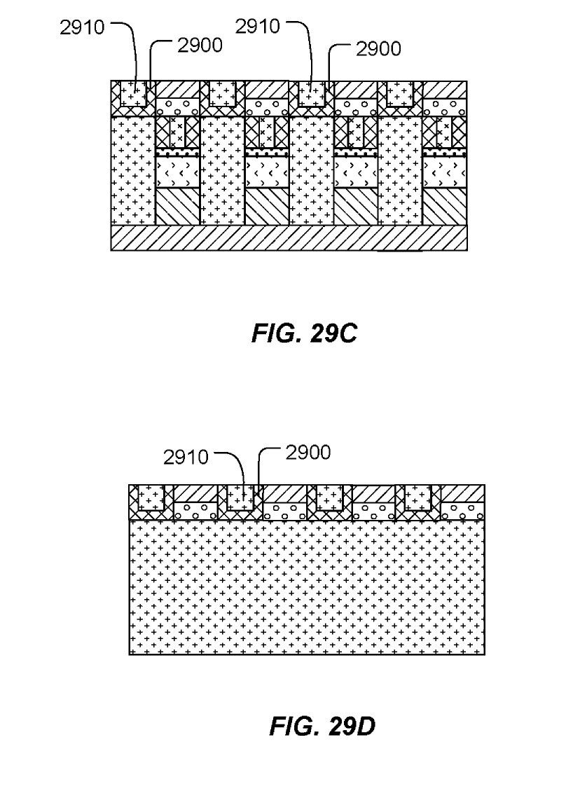

FIGS. 28-29 illustrate an alternative manufacturing technique to that illustrated in FIGS. 21-24.

A plurality of memory material strips 150 and bit lines 120 overlying corresponding memory material strips 150 are formed on the structure illustrated in FIGS. 20A-20D, resulting in the structure illustrated in the top view of FIG. 28A and the cross-sectional views of FIGS. 28B-28D. The strips 150 and bit lines 120 may be formed by forming a layer of memory material on the structure illustrated in FIGS. 20A-20D, forming a layer of bit line material on the layer of memory material, patterning a layer of photoresist on the layer of bit line material, and then etching the layer of bit line material and the layer of memory material using the patterned photoresist as an etch mask. The formation of the bit lines 120 and the strips of memory material 150 exposes the top surfaces of the plurality of dielectric filled second trenches 800.

Next, a first dielectric layer 2900 is formed on the bit lines 120, on the sidewall surfaces of the strips of memory material 150, and on the exposed top surfaces of the plurality of dielectric-filled second trenches 800. A second dielectric layer 2910 is formed on the first dielectric layer 2900, and a planarization process (for example CMP) is performed to expose the top surface of the bit lines 120, resulting in the structure illustrated in the top view of FIG. 29A and the cross-sectional views of FIGS. 29B-29D. In the illustrated embodiment layer 2900 comprises SiN and layer 2910 comprises silicon dioxide.

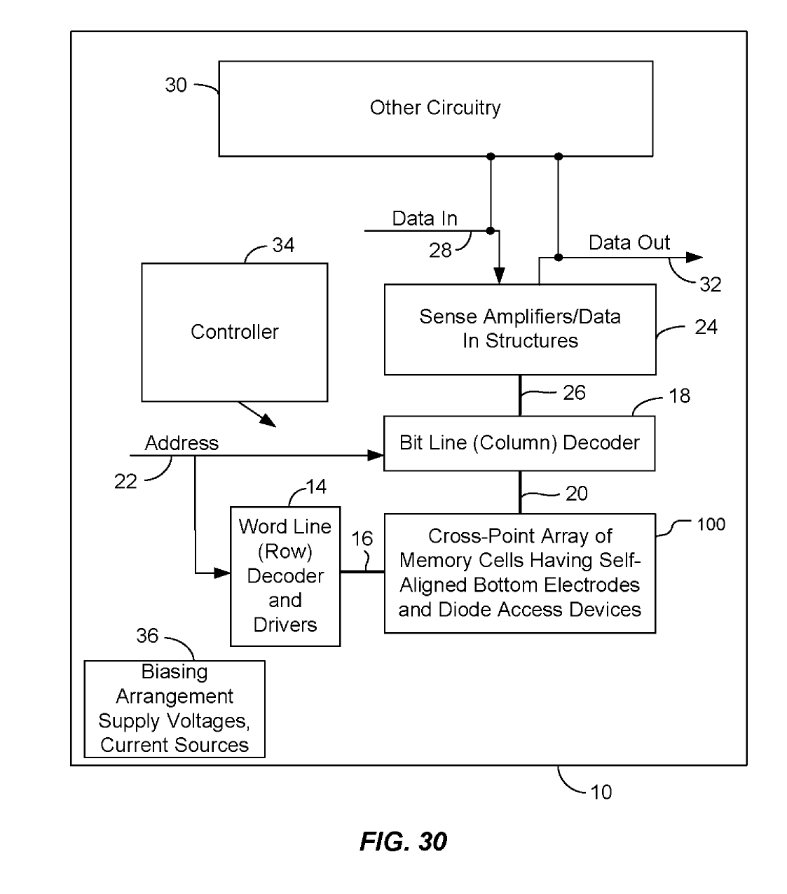

FIG. 30 is a simplified block diagram of an integrated circuit 10 including a cross-point memory array 100 of memory cells having self-aligned bottom electrodes and diode access devices as described herein. A word line decoder 14 is coupled to and in electrical communication with a plurality of word lines 16. A bit line (column) decoder 18 is in electrical communication with a plurality of bit lines 20 to read data from, and write data to, the phase change memory cells (not shown) in array 100. Addresses are supplied on bus 22 to word line decoder and drivers 14 and bit line decoder 18. Sense amplifiers and data-in structures in block 24 are coupled to bit line decoder 18 via data bus 26. Data is supplied via a data-in line 28 from input/output ports on integrated circuit 10, or from other data sources internal or external to integrated circuit 10, to data-in structures in block 24. Other circuitry 30 may be included on integrated circuit 10, such as a general purpose processor or special purpose application circuitry, or a combination of modules providing system-on-a-chip functionality supported by array 100. Data is supplied via a data-out line 32 from the sense amplifiers in block 24 to input/output ports on integrated circuit 10, or to other data destinations internal or external to integrated circuit 10.

A controller 34 implemented in this example, using a bias arrangement state machine, controls the application of bias arrangement supply voltages 36, such as read, program, erase, erase verify and program verify voltages. Controller 34 may be implemented using special-purpose logic circuitry as known in the art. In alternative embodiments, controller 34 comprises a general-purpose processor, which may be implemented on the same integrated circuit to execute a computer program to control the operations of the device. In yet other embodiments, a combination of special-purpose logic circuitry and a general-purpose processor may be utilized for implementation of controller 34.

Embodiments of the memory cells described herein include phase change based memory materials, including chalcogenide based materials and other materials, for the memory element. Chalcogens include any of the four elements oxygen (O), sulfur (S), selenium (Se), and tellurium (Te), forming part of group VIA of the periodic table. Chalcogenides comprise compounds of a chalcogen with a more electropositive element or radical. Chalcogenide alloys comprise combinations of chalcogenides with other materials such as transition metals. A chalcogenide alloy usually contains one or more elements from group IVA of the periodic table of elements, such as germanium (Ge) and tin (Sn). Often, chalcogenide alloys include combinations including one or more of antimony (Sb), gallium (Ga), indium (In), and silver (Ag). Many phase change based memory materials have been described in technical literature, including alloys of: Ga/Sb, In/Sb, In/Se, Sb/Te, Ge/Te, Ge/Sb/Te, In/Sb/Te, Ga/Se/Te, Sn/Sb/Te, In/Sb/Ge, Ag/In/Sb/Te, Ge/Sn/Sb/Te, Ge/Sb/Se/Te and Te/Ge/Sb/S. In the family of Ge/Sb/Te alloys, a wide range of alloy compositions may be workable. The compositions can be characterized as TeₐGe_{b}S_{100-(a-b)}. One researcher has described the most useful alloys as having an average concentration of Te in the deposited materials well below 70%, typically below about 60% and ranged in general from as low as about 23% up to about 58% Te and most preferably about 48% to 58% Te. Concentrations of Ge were above about 5% and ranged from a low of about 8% to about 30% average in the material, remaining generally below 50%. Most preferably, concentrations of Ge ranged from about 8% to about 40%. The remainder of the principal constituent elements in this composition was Sb. These percentages are atomic percentages that total 100% of the atoms of the constituent elements. (Ovshinsky 5,687,112 patent, cols. 10-11.) Particular alloys evaluated by another researcher include Ge₂Sb₂Te₅, GeSb₂Te₄ and GeSb₄Te₇ (Noboru Yamada, “Potential of Ge—Sb—Te Phase-Change Optical Disks for High-Data-Rate Recording”, SPIE v.3109, pp. 28-37 (1997).) More generally, a transition metal such as chromium (Cr), iron (Fe), nickel (Ni), niobium (Nb), palladium (Pd), platinum (Pt) and mixtures or alloys thereof may be combined with Ge/Sb/Te to form a phase change alloy that has programmable resistive properties. Specific examples of memory materials that may be useful are given in Ovshinsky '112 at columns 11-13, which examples are hereby incorporated by reference.

Chalcogenides and other phase change materials are doped with impurities in some embodiments to modify conductivity, transition temperature, melting temperature, and other properties of memory elements using the doped chalcogenides. Representative impurities used for doping chalcogenides include nitrogen, silicon, oxygen, silicon dioxide, silicon nitride, copper, silver, gold, aluminum, aluminum oxide, tantalum, tantalum oxide, tantalum nitride, titanium and titanium oxide. See, e.g., U.S. Pat. No. 6,800,504, and U.S. Patent Application Publication No. U.S. 2005/0029502.

Phase change alloys are capable of being switched between a first structural state in which the material is in a generally amorphous solid phase, and a second structural state in which the material is in a generally crystalline solid phase in its local order in the active channel region of the cell. These alloys are at least bistable. The term amorphous is used to refer to a relatively less ordered structure, more disordered than a single crystal, which has the detectable characteristics such as higher electrical resistivity than the crystalline phase. The term crystalline is used to refer to a relatively more ordered structure, more ordered than in an amorphous structure, which has detectable characteristics such as lower electrical resistivity than the amorphous phase. Typically, phase change materials may be electrically switched between different detectable states of local order across the spectrum between completely amorphous and completely crystalline states. Other material characteristics affected by the change between amorphous and crystalline phases include atomic order, free electron density and activation energy. The material may be switched either into different solid phases or into mixtures of two or more solid phases, providing a gray scale between completely amorphous and completely crystalline states. The electrical properties in the material may vary accordingly.

Phase change alloys can be changed from one phase state to another by application of electrical pulses. It has been observed that a shorter, higher amplitude pulse tends to change the phase change material to a generally amorphous state. A longer, lower amplitude pulse tends to change the phase change material to a generally crystalline state. The energy in a shorter, higher amplitude pulse is high enough to allow for bonds of the crystalline structure to be broken and short enough to prevent the atoms from realigning into a crystalline state. Appropriate profiles for pulses can be determined, without undue experimentation, specifically adapted to a particular phase change alloy. In following sections of the disclosure, the phase change material is referred to as GST, and it will be understood that other types of phase change materials can be used. A material useful for implementation of a PCRAM described herein is Ge₂Sb₂Te₅.

Other programmable resistive memory materials may be used in other embodiments of the invention, including N₂ doped GST, GexSby, or other material that uses different crystal phase changes to determine resistance; PrₓCa_{y}MnO₃, PrₓSr_{y}MnO₃, ZrOₓ, or other material that uses an electrical pulse to change the resistance state; 7,7,8,8-tetracyanoquinodimethane (TCNQ), methanofullerene 6,6-phenyl C61-butyric acid methyl ester (PCBM), TCNQ-PCBM, Cu-TCNQ, Ag-TCNQ, C60-TCNQ, TCNQ doped with other metal, or any other polymer material that has a bistable or multi-stable resistance state controlled by an electrical pulse.

An exemplary method for forming chalcogenide material uses PVD-sputtering or magnetron-sputtering method with source gas(es) of Ar, N2, and/or He, etc. at the pressure of 1 mTorr˜100 mTorr. The deposition is usually done at room temperature. A collimator with an aspect ratio of 1˜5 can be used to improve the fill-in performance. To improve the fill-in performance, a DC bias of several tens of volts to several hundreds of volts is also used. On the other hand, the combination of DC bias and the collimater can be used simultaneously.

A post-deposition annealing treatment in a vacuum or in an N₂ ambient is optionally performed to improve the crystallize state of chalcogenide material. The annealing temperature typically ranges from 100° C. to 400° C. with an anneal time of less than 30 minutes.

The thickness of chalcogenide material depends on the design of cell structure. In general, a chalcogenide material with thickness of higher than 8 nm can have a phase change characterization so that the material exhibits at least two stable resistance states.

While the present invention is disclosed by reference to the preferred embodiments and examples detailed above, it is to be understood that these examples are intended in an illustrative rather than in a limiting sense. It is contemplated that modifications and combinations will readily occur to those skilled in the art, which modifications and combinations will be within the spirit of the invention and the scope of the following claims.

What is claimed is:

1. A memory device comprising:
a plurality of word lines extending in a first direction;
a plurality of bit lines overlying the plurality of word lines and extending in a second direction, the bit lines crossing over the word lines at cross-point locations; and
a plurality of memory cells at the cross-point locations, wherein each memory cell comprises:
a diode having first and second sides aligned with sides of a corresponding word line in the plurality of word lines, the diode having a top surface;
a bottom electrode self-centered on the diode, the bottom electrode having a top surface with a surface area less than that of the top surface of the diode; and
a strip of memory material on the top surface of the bottom electrode, the strip of memory material underlying and in electrical communication with a corresponding bit line in the plurality of bit lines.

2. The device of claim 1, wherein the diode of each memory cell comprises a stack comprising:
a first doped semiconductor region having a first conductivity type on the corresponding word line;
a second doped semiconductor region having a second conductivity type opposite the first conductivity type, the second doped semiconductor region on the first doped semiconductor region and defining a pn junction therebetween; and
a conductive cap on the second doped semiconductor region.

3. The device of claim 2, wherein:
the first doped semiconductor region of each memory cell comprises n-type doped semiconductor material;
the second doped semiconductor region of each memory cell comprises p-type doped semiconductor material; and
the conductive cap of each memory cell comprises a silicide.

4. The device of claim 3, wherein the plurality of word lines comprise n-type doped semiconductor material more highly doped than that of the first doped semiconductor region of each memory cell.

5. The device of claim 1, wherein the bottom electrode of each memory cell has an outer surface, and each memory cell further comprises a dielectric spacer on the outer surface of the bottom electrode and having sides aligned with the sides of the diode.

6. The device of claim 5, wherein the bottom electrode of each memory cell has an inner surface such that the top surface of the bottom electrode has a ring-shape, and each memory cell further comprises a fill material within an interior defined by the inner surface of the bottom electrode.

7. The device of claim 1, wherein the bottom electrode of each memory cell comprises:
a first conductive element having sides aligned with the sides of the diode and having a width substantially the same as that of the diode; and
a second conductive element self-centered on the first conductive element and having a width less than that of the first conductive element.

8. The device of claim 1, wherein:
the word lines have word line widths and adjacent word lines are separated by a word line separation distance;
the bit lines have bit line widths and adjacent bit lines are separated by a bit line separation distance; and
each of the memory cells in the plurality of memory cells have a memory cell area, the memory cell area having a first side along the first direction and a second side along the second direction, the first side having a length equal to the summation of the bit line width and the bit line separation distance, the second side having a length equal to the summation of the word line width and the word line separation distance.

9. A method for manufacturing a memory device, the method comprising:
forming a plurality of word lines extending in a first direction;
forming a plurality of bit lines overlying the plurality of word lines and extending in a second direction, the bit lines crossing-over the word lines at cross-point locations; and
forming a plurality of memory cells at the cross-point locations, wherein each memory cell comprises:
a diode having first and second sides aligned with sides of a corresponding word line in the plurality of word lines, the diode having a top surface;
a bottom electrode self-centered on the diode, the bottom electrode having a top surface with a surface area less that that of the top surface of the diode; and
a strip of memory material on the top surface of the bottom electrode, the strip of memory material underlying and in electrical communication with a corresponding bit line in the plurality of bit lines.

10. The method of claim 9, wherein the diode of each memory cell comprises a stack comprising:
a first doped semiconductor region having a first conductivity type on the corresponding word line;
a second doped semiconductor region having a second conductivity type opposite the first conductivity type, the second doped semiconductor region on the first doped semiconductor region and defining a pn junction therebetween; and
a conductive cap on the second doped semiconductor region.

11. The method of claim 10, wherein:
the first doped semiconductor region of each memory cell comprises n-type doped semiconductor material;
the second doped semiconductor region of each memory cell comprises p-type doped semiconductor material; and
the conductive cap of each memory cell comprises a silicide.

12. The method of claim 11, wherein the plurality of word lines comprise n-type doped semiconductor material more heavily doped than that of the first doped semiconductor region of each memory cell.

13. The method of claim 9, wherein the bottom electrode of each memory cell has an outer surface, and each memory cell further comprises a dielectric spacer on the outer surface of the bottom electrode and having sides aligned with the sides of the diode.

14. The method of claim 13, wherein the bottom electrode of each memory cell has an inner surface such that the top surface of the bottom electrode has a ring-shape, and each memory cell further comprises a fill material within an interior defined by the inner surface of the bottom electrode.

15. The method of claim 9, wherein the bottom electrode of each memory cell comprises:
a first conductive element having sides aligned with the sides of the diode and having a width substantially the same as that of the diode; and
a second conductive element self-centered on the first conductive element and having a width less than that of the first conductive element.

16. The method of claim 9, wherein:
the word lines have word line widths and adjacent word lines are separated by a word line separation distance;
the bit lines have bit line widths and adjacent bit lines are separated by a bit line separation distance; and
each of the memory cells in the plurality of memory cells have a memory cell area, the memory cell area having a first side along the first direction and a second side along the second direction, the first side having a length equal to the summation of the bit line width and the bit line separation distance, the second side having a length equal to the summation of the word line width and the word line separation distance.

17. A method for manufacturing a memory device, the method comprising:
forming a structure comprising word line material, diode material on the layer of word line material, first material on the diode material, and second material on the layer of first material;
forming a plurality of dielectric-filled first trenches in the structure extending in a first direction to define a plurality of strips, each strip including a word line comprising word line material;
forming a plurality of dielectric-filled second trenches down to the word lines and extending in a second direction to define a plurality of stacks, each stack including (a) a diode comprising the diode material on a corresponding word line and having a top surface, (b) a first element comprising first material on the diode, and (c) a second element comprising second material on the first element;
forming a plurality of bottom electrodes on a corresponding diode using the first elements and the second elements of the stacks; and
forming strips of memory material on top surfaces of the bottom electrodes and forming bit lines on the strips of memory material.

18. The method of claim 17, further comprising:
forming an oxide layer on the bit lines;
forming an array of conductive vias extending through the oxide layer to contact a corresponding word line;
forming a plurality of global word lines on the oxide layer and in contact with a corresponding conductive via in the array of conductive vias.

19. The method of claim 17, wherein the step of forming strips of memory material and forming bit lines on the strips of memory material comprises:
forming memory material on the top surfaces of the bottom electrodes;
forming bit line material on the memory material;
patterning the memory material and the bit line material to expose top surfaces of the plurality of dielectric-filled second trenches;
forming a first dielectric layer on the bit lines, on sidewall surfaces of the strips of memory material, and on the exposed top surfaces of the plurality of dielectric-filled second trenches;
forming a second dielectric layer on the first dielectric layer; and
performing a planarizing process to expose top surfaces of the bit lines.

20. The method of claim 17, wherein the step of forming strips of memory material and bit lines on the strips of memory material comprises:
forming sacrificial material strips extending in the second direction and contacting the top surfaces of the plurality of bottom electrodes;
forming strips of dielectric material between the sacrificial material strips;
removing the sacrificial material strips to expose the top surfaces of the bottom electrodes and define trenches between the strips of dielectric material;
forming strips of memory material within the trenches to contact the top surfaces of the bottom electrodes; and
forming bit lines on the strips of memory material.

21. The method of claim 17, wherein the forming a plurality of bottom electrodes comprises:
removing material from the plurality of dielectric-filled first and second trenches down to expose sidewall surfaces of the second elements;
reducing the width of the second elements;
etching the first elements using the reduced width second elements as an etch mask, thereby forming bottom electrodes comprising first element material and defining openings surrounding the bottom electrodes; and
forming dielectric spacers within the openings.

22. The method of claim 17, wherein the forming a plurality of bottom electrodes comprises:
removing the second elements to form vias overlying the first elements;
forming sidewall spacers within the vias;
etching the first elements using the sidewall spacers as an etch mask, thereby forming dielectric spacers comprising first material and defining openings;
forming bottom electrode material within openings defined by the dielectric spacers using a process that does not completely fill the openings;
forming a dielectric fill material on the bottom electrode material to fill the openings defined by the dielectric spacers; and
performing a planarizing process to remove the sidewall surfaces, thereby forming the plurality of bottom electrodes, each bottom electrode having an inner surface such that the top surface of the bottom electrode has a ring-shape, the dielectric fill material within an interior defined by the inner surface of the bottom electrode.
